(19) United States
(12) Patent Application Publication
(10) Pub. No.: US 2026/0336687 A1
(43) Pub. Date: Oct. 29, 2026

(54) MOTOR CONTROL DEVICE

(71) Applicant: DENSO CORPORATION, Kariya-city (JP)

(72) Inventors: Kunihiko MATSUDA, Kariya-city (JP); Toshihiro FUJITA, Kariya-city (JP); Nao UEMATSU, Kariya-city (JP); Atsushi SAITO, Kariya-city (JP)

(21) Appl. No.: 19/707,591

(22) Filed: Jun. 15, 2026

Related U.S. Application Data
(63) Continuation of application No. PCT/JP2024/044571, filed on Dec. 17, 2024.

(30) Foreign Application Priority Data
Dec. 18, 2023 (JP) 2023-212700

(51) Int. Cl. B62D 5/04; H02P 25/22; H02P 27/08; H10D 80/30; H10W 40/50; H10W 70/40; H10W 70/60; H10W 72/60; H10W 74/10; H10W 90/00; H10W 90/10; H10W 90/24

(52) U.S. Cl. CPC B62D 5/046; H02P 25/22; H02P 27/08; H10D 80/30; H10W 40/50; H10W 70/424; H10W 70/479; H10W 70/611; H10W 72/634; H10W 72/642; H10W 72/647; H10W 74/114; H10W 90/10; H10W 90/24; H10W 90/762; H10W 90/766; H10W 90/753

(57) ABSTRACT

A motor control device for driving a motor having a plurality of motor windings, includes a plurality of driver components and a substrate on which the driver components are mounted. The driver components each includes a high-side chip including an upper arm element connected to a high potential side, a low-side chip including a lower arm element connected to a low potential side of the upper arm element, and a control chip including a pre-driver IC configured to output drive signals to the upper arm element and the lower arm element. The driver components are arranged on the substrate in regions divided for each of the driver components related to energization control of the respective motor windings. In each region, the control chip, the high-side and low-side chips, and a motor wire connection portion to which the motor winding is connected are arrayed in this order from one side.

### CROSS REFERENCE TO RELATED APPLICATIONS

The present application is a continuation application of International Patent Application No. PCT/JP2024/044571 filed on Dec. 17, 2024, which designated the U.S. and claims the benefit of priority from Japanese Patent Application No. 2023-212700 filed on Dec. 18, 2023. The entire disclosures of all of the above applications are incorporated herein by reference.

### TECHNICAL FIELD

The present disclosure relates to a motor control device.

### BACKGROUND

As a related art, a motor control device that controls a motor having two sets of motor windings is known. For example, it is proposed that the motor control device has a configuration of two systems in which an inverter circuit and a control unit are provided corresponding to motor windings.

### SUMMARY

According to an aspect of the present disclosure, a motor control device for driving a motor having a plurality of motor windings, may include a plurality of driver components and a substrate. The plurality of driver components may each include a high-side chip including an upper arm element connected to a high potential side, a low-side chip including a lower arm element connected to a low potential side of the upper arm element, and a control chip including a pre-driver integrated circuit (IC) configured to output drive signals to the upper arm element and the lower arm element. The driver components may be mounted on the substrate. The driver components may be disposed on the substrate in regions divided for each of the components related to energization control of the respective motor windings, and the control chip, the high-side and low-side chips and a motor wire connection portion to which the motor winding is connected are arrayed in this order from one side in each region.

### BRIEF DESCRIPTION OF DRAWINGS

Objects, features, and advantages of the present disclosure will become more apparent from the following detailed description with reference to the accompanying drawings. The drawings include:

FIG. 1 is a schematic configuration diagram illustrating an electric power steering device according to a first embodiment;

FIG. 2 is a block diagram illustrating an ECU according to the first embodiment;

FIG. 3 is a circuit diagram for describing a driver circuit according to the first embodiment;

FIG. 4 is a circuit diagram for describing a driver component according to the first embodiment;

FIG. 5 is a circuit diagram for describing the driver component according to the first embodiment;

FIG. 6 is a circuit diagram for describing the driver component according to the first embodiment;

FIG. 7 is a plan view illustrating the driver component according to the first embodiment;

FIG. 8 is a sectional view taken along line VIII-VIII in FIG. 7;

FIG. 9 is a schematic diagram for describing a substrate arrangement according to the first embodiment;

FIG. 10 is a schematic diagram for describing the substrate arrangement according to the first embodiment;

FIG. 11 is a schematic diagram for describing the substrate arrangement according to the first embodiment;

FIG. 12 is an explanatory diagram for describing a connection between the microcomputers and the components in the two systems;

FIG. 13 is an explanatory diagram for describing a connection between the microcomputers and the components in three systems;

FIG. 14A is an explanatory diagram illustrating an inter-system connection line according to the first embodiment;

FIG. 14B is an explanatory diagram illustrating the inter-system connection line according to the first embodiment;

FIG. 15 is an explanatory diagram illustrating an isolator according to the first embodiment;

FIG. 16 is an explanatory diagram for describing a communication configuration between the microcomputer and the driver component according to the first embodiment;

FIG. 17 is an explanatory diagram for describing a communication configuration between the microcomputer and the driver component according to the first embodiment;

FIG. 18 is a time chart for describing data communication according to the first embodiment;

FIG. 19 is a schematic diagram illustrating an arrangement in a case where motor windings have two systems;

FIG. 20 is a schematic diagram illustrating an arrangement in a case where motor windings have four systems;

FIG. 21 is a time chart for describing communication between a processing core and a pre-driver IC according to the first embodiment;

FIG. 22 is a time chart for describing communication with the pre-driver IC in a case where some of the processing cores according to the first embodiment fail;

FIG. 23 is an explanatory diagram for describing an inter-system connection line according to the first embodiment;

FIG. 24 is a block diagram for describing driving of the power supply relay and the reverse connection protection relay according to the first embodiment;

FIG. 25 is a block diagram for describing a redundant configuration in the microcomputer according to the first embodiment;

FIG. 26 is a flowchart for describing a clock monitoring process according to the first embodiment;

FIG. 27 is a flowchart for describing a power supply monitoring process according to the first embodiment;

FIG. 28 is a block diagram for describing driving of the power supply relay and the reverse connection protection relay according to a second embodiment;

FIG. 29 is a block diagram for describing driving of a power supply relay and a reverse connection protection relay according to a third embodiment;

FIG. 30 is a block diagram for describing an ECU according to the first embodiment;

FIG. 31 is a block diagram for describing an ECU according to a fourth embodiment;

FIG. 32 is a block diagram for describing an ECU according to a fifth embodiment;

FIG. 33 is a block diagram for describing an ECU according to a sixth embodiment;

FIG. 34 is a schematic diagram illustrating an arrangement in a case where motor windings have three systems;

FIG. 35 is a block diagram for describing an ECU according to a seventh embodiment;

FIG. 36 is a block diagram for describing an ECU according to an eighth embodiment;

FIG. 37 is a block diagram for describing an ECU according to a ninth embodiment;

FIG. 38 is a block diagram for describing computation timing according to the ninth embodiment;

FIG. 39 is a block diagram for describing an ECU according to a tenth embodiment;

FIG. 40 is a time chart for describing the operation of a motor relay according to the tenth embodiment;

FIG. 41 is a schematic diagram for describing a substrate arrangement according to an eleventh embodiment;

FIG. 42 is a schematic diagram for describing a substrate arrangement according to the eleventh embodiment;

FIG. 43 is a schematic diagram for describing a substrate arrangement according to a twelfth embodiment;

FIG. 44 is a block diagram for describing an ECU according to the twelfth embodiment;

FIG. 45 is a block diagram for describing an ECU according to a thirteenth embodiment;

FIG. 46 is a time chart for describing the operation of a motor relay according to the thirteenth embodiment;

FIG. 47 is a time chart for describing the operation of the motor relay according to the thirteenth embodiment;

FIG. 48 is a schematic diagram for describing a substrate arrangement according to a fourteenth embodiment;

FIG. 49 is a schematic diagram for describing a substrate arrangement according to a fifteenth embodiment;

FIG. 50 is a plan view illustrating a driver component according to a sixteenth embodiment;

FIG. 51 is a cross-sectional view taken along line LI-LI of FIG. 50;

FIG. 52 is a cross-sectional view taken along line LII-LII of FIG. 50;

FIG. 53 is a plan view illustrating a driver component according to a seventeenth embodiment;

FIG. 54 is a cross-sectional view taken along line LIV-LIV of FIG. 53;

FIG. 55 is a cross-sectional view taken along line LV-LV of FIG. 53; and

FIG. 56 is a plan view illustrating a driver component according to an eighteenth embodiment.

### DETAILED DESCRIPTION

In a motor control device that has two systems of an inverter circuit and a control unit corresponding to two sets of motor windings of a motor, if an additional failure occurs while control is being continued after occurrence of a first failure, there is a possibility that driving of the motor cannot be continued. From the viewpoint of functional safety, when further redundancy is provided, for example four systems or the like, there is a possibility that the wiring becomes complicated. The present disclosure provides a motor control device capable of simplifying substrate wiring in a redundant configuration.

According to an aspect of the present disclosure, a motor control device that controls a motor having a plurality of motor windings, includes a plurality of driver components and a substrate on which the plurality of driver components are mounted. The driver components each includes a high-side chip including an upper arm element connected to a high potential side, a low-side chip including a lower arm element connected to a low potential side of the upper arm element, and a control chip including a pre-driver integrated circuit (IC) configured to output drive signals to the upper arm element and the lower arm element.

The driver components are arranged on the substrate by dividing regions for each of the driver components related to energization control of the respective motor windings, and in each region, the control chip, the high-side chip and the low-side chip, and a motor wire connection portion to which the motor winding is connected are arrayed in this order from one side. With this configuration, substrate wiring between the driver components and the motor windings can be simplified.

Hereinafter, a motor control device according to the present disclosure will be described with reference to the drawings. In the following embodiments, substantially the same components are denoted by the same reference numerals, and description thereof will be omitted as appropriate.

### First Embodiment

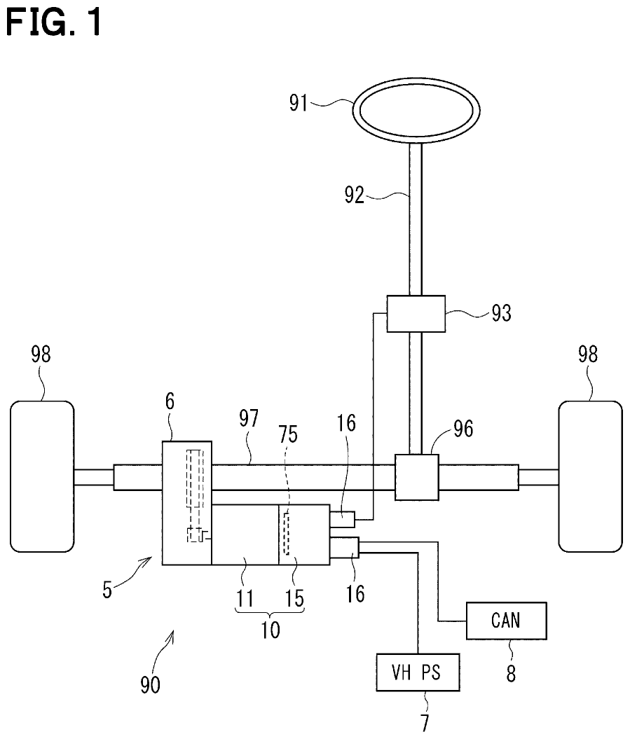

A first embodiment will be described with reference to FIGS. 1 to 27. As illustrated in FIG. 1, a drive device 10 includes a motor 11 and an ECU 15 as a communication device, and is applied to, for example, an electric power steering device 5 which is a steering device for assisting a steering operation of a vehicle. FIG. 1 illustrates an overall configuration of a steering system 90 including the electric power steering device 5. The steering system 90 includes a steering wheel 91 which is a steering member, a steering shaft 92, a pinion gear 96, a rack shaft 97, wheels 98, the electric power steering device 5, and the like.

The steering wheel 91 is connected to the steering shaft 92. The steering shaft 92 is provided with a torque sensor 93 that detects steering torque. The pinion gear 96 is provided at a distal end of the steering shaft 92. The pinion gear 96 meshes with the rack shaft 97. A pair of wheels 98 is coupled to both ends of the rack shaft 97 via tie rods or the like.

When a driver rotates the steering wheel 91, the steering shaft 92 connected to the steering wheel 91 rotates. The rotational movement of the steering shaft 92 is converted into a linear movement of the rack shaft 97 by the pinion gear 96. The pair of wheels 98 is steered at an angle corresponding to the displacement amount of the rack shaft 97.

The electric power steering device 5 includes the drive device 10, a reduction gear 6 as a power transmission unit that decelerates the rotation of the motor 11 and transmits the rotation to the rack shaft 97, and the like. The electric power steering device 5 of the present embodiment is a so-called “rack assist type”, but may be a so-called “column assist type” or the like that transmits the rotation of the motor 11 to the steering shaft 92.

The drive device 10 is a so-called “electromechanical integrated type” in which the ECU 15 is integrally provided on one side of the motor 11 in the axial direction. The ECU 15 includes a connector 16, and is connected to a vehicle power supply 7, a vehicle communication network 8, and the torque sensor 93 via the connector 16. The vehicle power supply 7 includes power supplies 501 and 502 described later. The vehicle communication network 8 is, for example, a controller area network (CAN), and is described as a “CAN” in the figure. In the figures, “PS” represents power supply, “OSC” represents oscillator, “MCP” represents microcomputer. Also, “VH” represents vehicle, and “TRQ” represents torque. “CMND” represents command, “INF” represents information, “ARBT” represents arbitration and “RC” represents reverse connection. “SGN” represents signal, “STP-DWN” represents step down. “COMM” represents communication.

The ECU 15 is disposed coaxially with the motor 11 and opposite to the output shaft of the motor 11. Here, “coaxial” means that, for example, an error or deviation regarding assembly or design is permitted. Hereinafter, the axial direction of the motor 11 is regarded as the axial direction of the drive device 10, and is simply referred to as the “axial direction”. The same applies to the “radial direction” and the “circumferential direction”.

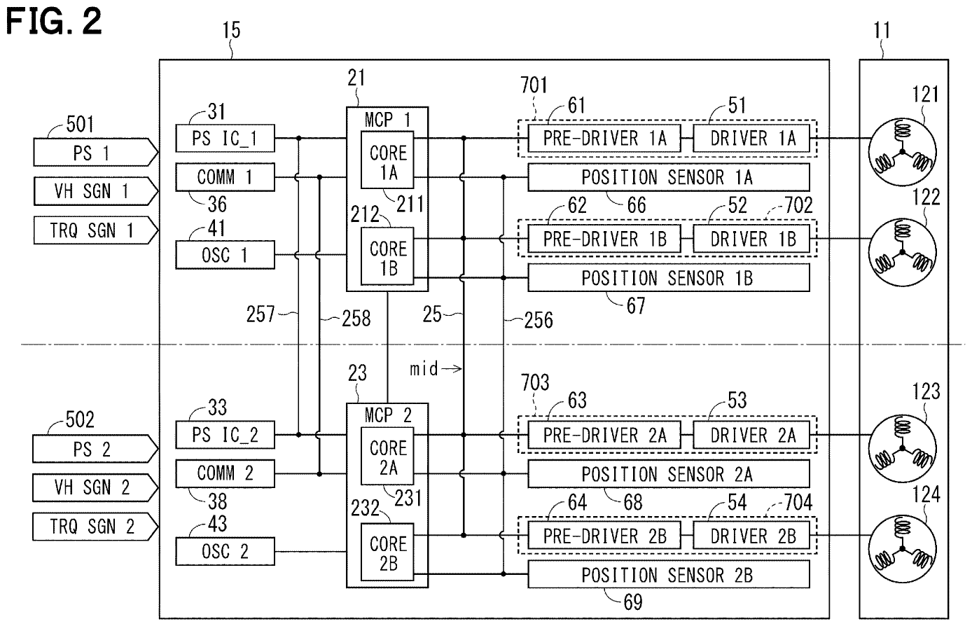

As illustrated in FIG. 2, the motor 11 is, for example, a three-phase brushless motor, and includes four motor windings 121 to 124. The motor 11 outputs part or all of the torque required for steering, is driven by power supplied from the power supplies 501 and 502, and rotates the reduction gear 6 forward and backward.

The ECU 15 includes microcomputers 21 and 23, power supply ICs 31 and 33, communication units 36 and 38, oscillators 41 and 43, driver circuits 51 to 54, pre-driver ICs 61 to 64, position sensors 66 to 69, and the like. Note that the description of suffixes “1”, “2”, “1A”, “2A”, “1B”, “2B”, and the like indicates that they are provided correspondingly, and reference numerals are appropriately omitted for configurations that can be identified by suffixes. Each component constituting the ECU 15 is mounted on a substrate 75 provided substantially parallel to one side end face of the motor 11 in the axial direction (see FIG. 1). Although one substrate 75 is illustrated in FIG. 1, a plurality of substrates may be provided.

The microcomputer 21 includes processing cores 211 and 212 each having a lockstep. The microcomputer 23 includes processing cores 231 and 232 each having a lockstep. The microcomputers 21 and 23 are provided to be able to transmit and receive information to and from each other by microcomputer-to-microcomputer communication. In the present embodiment, the microcomputers 21 and 23 are similarly configured, but may have different performances and configurations. The microcomputers 21 and 23 will be described later in detail.

Power is supplied to the microcomputer 21 from the power supply IC 31, and power is supplied to the microcomputer 23 from the power supply IC 33. The power supply ICs 31 and 33 are power management ICs (PMIC). In the present embodiment, power is supplied from the power supply 501 to the component on the upper side of the alternate long and short dash line in FIG. 2, and power is supplied from the power supply 502 to the component on the lower side of the alternate long and short dash line. That is, the drive device 10 of the present embodiment has “two power supply systems” to which power is supplied from the two power supplies 501 and 502.

The communication units 36 and 38 are used to transmit and receive various types of information. The communication units 36 and 38 are connected to the vehicle communication network 8 and acquire a vehicle signal from the vehicle communication network 8. The oscillators 41 and 43 are clock sources such as a crystal oscillator and a ceramic oscillator.

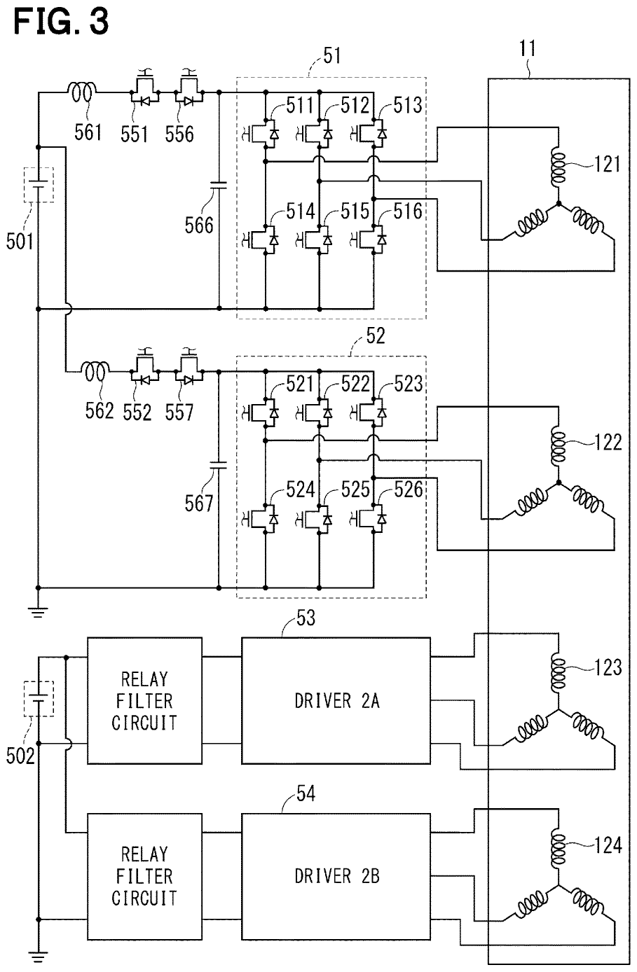

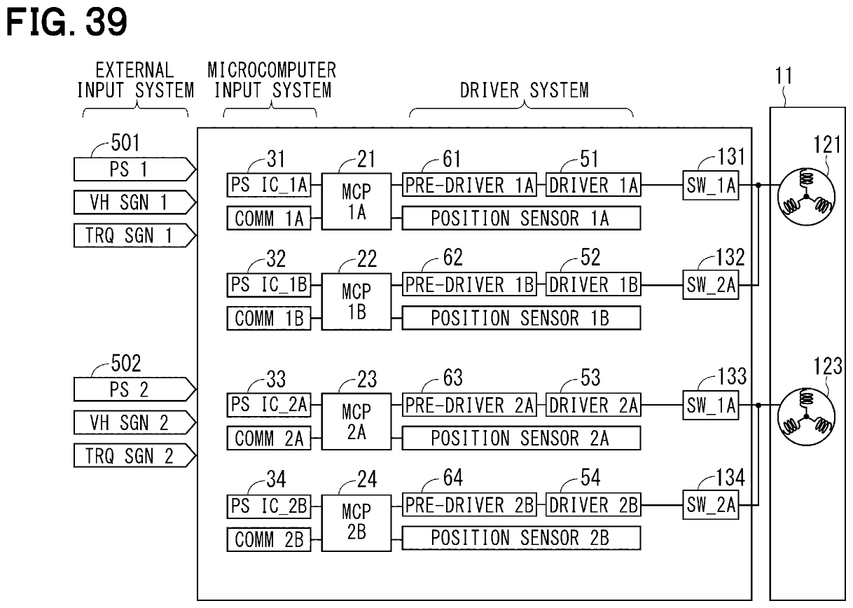

As illustrated in FIG. 3, the driver circuit 51 includes six switching elements 511 to 516 and is provided corresponding to the winding 121. The driver circuit 52 includes six switching elements 521 to 526 and is provided corresponding to the winding 122. The driver circuit 53 includes six switching elements and is provided corresponding to the winding 123. The driver circuit 54 includes six switching elements and is provided corresponding to the winding 124. Motor relays 131 to 134 are provided between the driver circuits 51 to 54 and the windings 121 to 124 (see FIG. 39).

In the driver circuit 51, the switching elements 511 to 513 are provided on the high potential side, and the switching elements 514 to 516 are provided on the low potential side, and they are bridge-connected. The switching elements 511 and 514 are connected to the U phase of the winding 121, the switching elements 512 and 515 are connected to the V phase of the winding 121, and the switching elements 513 and 516 are connected to the W phase of the winding 121.

In addition, in the driver circuit 52, the switching elements 521 to 523 are provided on the high potential side, and the switching elements 524 to 526 are provided on the low potential side, and they are bridge-connected. The switching elements 521 and 524 are connected to the U phase of the winding 122, the switching elements 522 and 525 are connected to the V phase of the winding 122, and the switching elements 523 and 526 are connected to the W phase of the winding 122. Hereinafter, the switching element on the high potential side is referred to as an upper arm element, and the switching element on the low potential side is referred to as a lower arm element as appropriate. The switching element of the present embodiment is a metal oxide semiconductor field effect transistor (MOSFET), but may be an insulated gate bipolar transistor (IGBT), a bipolar transistor, or the like.

The driver circuits 51 and 52 are connected to the power supply 501. A power supply relay 551, a reverse connection protection relay 556, a choke coil 561, and a capacitor 566 are provided between the power supply 501 and the driver circuit 51. The choke coil 561 and the capacitor 566 constitute a filter circuit. A power supply relay 552, a reverse connection protection relay 557, a choke coil 562, and a capacitor 567 are provided between the power supply 501 and the driver circuit 52. The choke coil 562 and the capacitor 567 constitute a filter circuit. The driver circuits 53 and 54 are connected to the power supply 502. The circuit configurations of the driver circuits 53 and 54, and the power supply relay, the reverse connection protection relay, and the filter circuit provided between the power supply 502 and the driver circuits 53 and 54 are similar to those of the driver circuits 51 and 52, the power supply relays 551 and 552, and the like, and thus the description thereof will be omitted.

Returning to FIG. 2, the pre-driver ICs 61 to 64 are provided corresponding to the driver circuits 51 to 54. The pre-driver ICs 61 and 62 are provided to be capable of performing digital communication with the microcomputer 21, and the pre-driver ICs 63 and 64 are provided to be capable of performing digital communication with the microcomputer 23. The microcomputers 21 and 23 transmit three-phase drive commands of the motor 11 as a set of digital signals to each of the pre-driver ICs 61 to 64.

Specifically, the pre-driver IC 61 is communicably connected to the processing core 211, the pre-driver IC 62 is communicably connected to the processing core 212, the pre-driver IC 63 is communicably connected to the processing core 231, and the pre-driver IC 64 is communicably connected to the processing core 232. In addition, the communication lines connecting the pre-driver ICs 61 to 64 and the processing cores 211, 212, 231, and 232 are connected by an inter-system connection line 25.

By digitizing communication between the microcomputer and the pre-driver and providing the inter-system connection line 25, for example, even in a case where an abnormality occurs in one processing core, commands from other normal processing cores to all the pre-driver ICs 61 to 64 can be continued. Note that the inter-system connection line 25 means that four connection lines connecting the cores and the pre-driver ICs are connected so as to have the same potential. Therefore, for example, even if a disconnection occurs at a location indicated by an arrow “mid” in FIG. 2, signal transmission and reception can be performed between the processing cores 1A and 1B and the pre-drivers 2A and 2B.

The inter-system connection line 25 is provided with an isolator 28 to be described later (not illustrated in FIG. 2). The isolator 28 may be provided at any position of the inter-system connection line 25. In addition, a similar effect can be obtained by imparting an isolator function to a necessary component.

The position sensors 66 to 69 detect the rotation of the motor 11. The position sensors 66 to 69 are connected to the processing cores 211, 212, 231, and 232, respectively. The communication lines connecting the position sensors 66 to 69 and the microcomputers 21 and 23 are connected by an inter-system connection line 256. The communication lines connecting the power supply ICs 31 and 33 and the microcomputers 21 and 23 are connected by an inter-system connection line 257, and the communication lines connecting the communication units 36 and 38 and the microcomputers 21 and 23 are connected by an inter-system connection line 258. Note that the inter-system connection line 256 to 258 may be omitted.

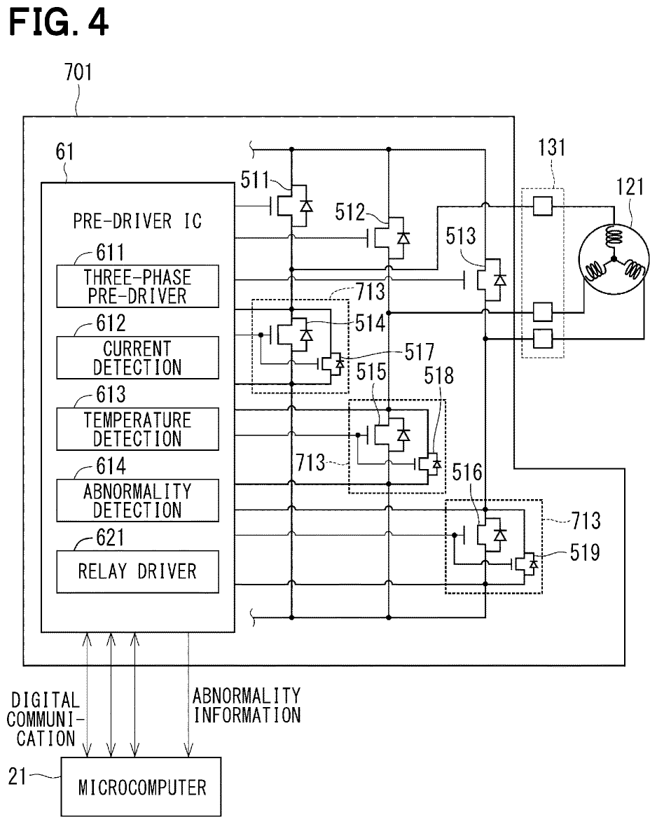

The pre-driver IC will be described with reference to FIG. 4. Here, the pre-driver IC 61 will be described as a representative example. As illustrated in FIG. 4, the pre-driver IC 61 includes a three-phase pre-driver circuit 611 that transmits a gate signal to the switching element constituting the driver circuit 51. In addition, the pre-driver IC 61 includes a current detection circuit 612, a temperature detection circuit 613, an abnormality detection unit 614, a relay driver circuit 621, and the like.

The pre-driver circuit 611 outputs a gate signal as a drive signal to the switching elements 511 to 516 based on a drive command from the microcomputer 21. The current detection circuit 612 detects a motor current based on detection values of current detection elements 517 to 519. Each of the current detection elements 517 to 519 of the present embodiment is a current sense MOS and is built in a low-side chip 713 to be described later. The current sense MOS may be built in a high-side chip 712 or may be a chip different from the upper and lower arm elements.

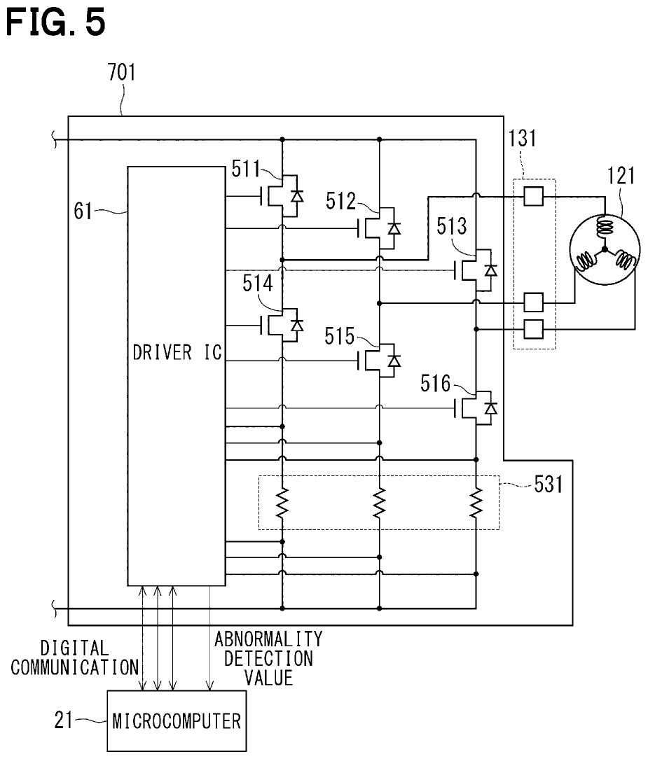

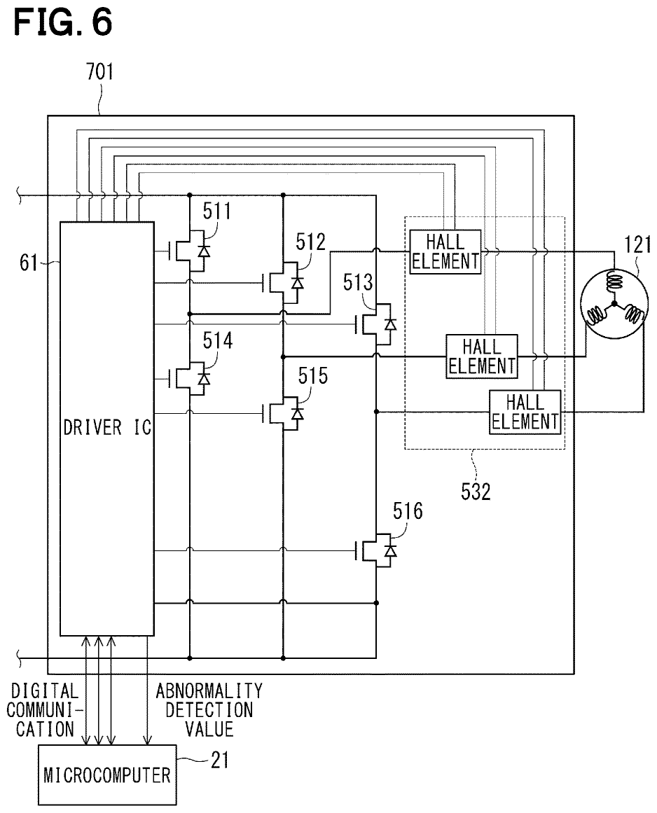

As illustrated in FIG. 5, the current detection element 531 may be a shunt resistor provided in an arm of each phase. In the example of FIG. 5, the shunt resistor is provided on the low potential side of the lower arm element, but may be provided on the high potential side of the upper arm element. Furthermore, as illustrated in FIG. 6, the current detection element 532 may be a Hall element provided between a connection point of the upper and lower arm elements and the motor winding. In FIGS. 5 and 6, the current detection elements 531 and 532 are described as being provided in the driver component 701 to be described later, but may be provided outside the driver component 701. In FIG. 6, the description of the motor relay 131 is omitted.

Returning to FIG. 4, the temperature detection circuit 613 detects the temperatures of the driver circuit 50 and the pre-driver IC 61 based on a detection value of a temperature detection element (not illustrated). The abnormality detection unit 614 monitors an abnormality of the driver circuit 50 based on a gate-source potential difference and a drain-source potential difference of the element constituting the driver circuit 50, and a drive command from the microcomputer 21. For example, the abnormality detection unit 614 monitors an abnormality such as a short circuit or a terminal open based on a potential difference. In addition, the abnormality detection unit 614 monitors an overheating abnormality based on temperature information and an abnormality of the pre-driver IC 61 itself.

The relay driver circuit 621 outputs a gate signal as a drive signal to the power supply relay 551, the reverse connection protection relay 556, and the motor relay 131 based on a drive command from the microcomputer 21.

The pre-driver IC 61 transmits the current detection value, the temperature information, and the abnormality information to the microcomputer 21. Information transmission from the pre-driver IC 61 to the microcomputer 21 may be digital communication or analog communication.

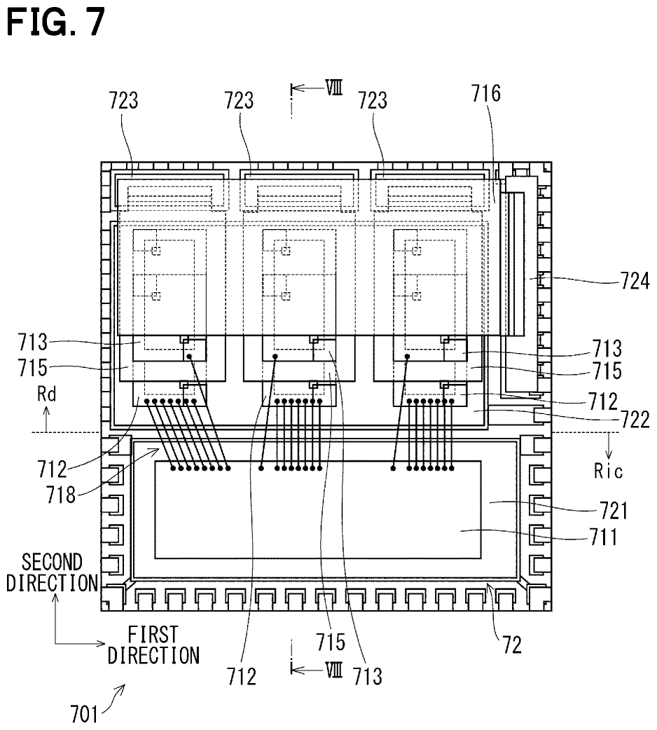

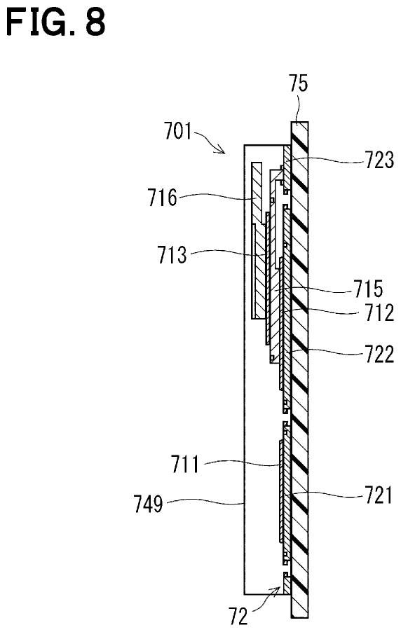

In the present embodiment, the driver circuits 51 to 54 and the pre-driver ICs 61 to 64 that are provided correspondingly are provided as respective driver components 701 to 704 in the common package. FIGS. 7 and 8 illustrate the driver component 701 including the driver circuit 51 and the pre-driver IC 61. In FIG. 7, a sealing part 749 is omitted in order to describe the inside of the component, and in FIG. 8, hatching of the sealing part 749 is omitted.

As illustrated in FIGS. 7 and 8, the driver component 701 includes a control chip 711, a high-side chip 712, a low-side chip 713, an intermediate clip 715, a ground clip 716, a lead frame 72, and the like, and is sealed by the sealing part 749. The sealing part 749 is formed in a substantially rectangular shape in a plan view, and has a terminal along the outer edge. Regardless of the terminal arrangement and shape, the terminal may be a non-lead type or may be formed to protrude to the outside of the sealing part 749. The driver component 701 is provided with a temperature detection element such as a temperature sensitive diode. As in the current detection elements 517 to 519, the temperature detection element may be built in the high-side chip 712 or the low-side chip 713.

The lead frame 72 includes a control land 721, a power land 722, an output land 723, and a ground land 724. The rear face of the lead frame 72 is exposed from the sealing part 749 and is electrically connected to the wiring pattern of the substrate 75 by solder bonding or the like. Note that not all the lands are required to be connected to the substrate 75 on the back face. Hereinafter, a region on the control land 721 side is referred to as an IC region Ric, and a region on the power land 722 side is referred to as a drive element region Rd. Further, in the driver component 701, an end portion on the power land 722 side (the upper side of the sheet of FIG. 7) is defined as an element-side end portion, and an end portion on the control land 721 side (the lower side of the sheet of FIG. 7) is defined as an IC-side end portion.

The control chip 711 constitutes the pre-driver IC 61 and is disposed on the control land 721. In the present embodiment, the control land 721 on which the control chip 711 is mounted has the ground potential, but in a case of using a control land on which the back face of the control chip 711 is insulated, the potential of the control land 721 may be a potential other than the ground potential, such as a power supply potential.

A control terminal, which is a terminal provided in a control region Rc, is connected to the microcomputer 21, the power supply IC 31, other pre-driver ICs 62 to 64, and the like. The control terminal includes a clock signal terminal, a PWM frequency synchronization terminal, a sample hold terminal, and the like. In a case where communication between the microcomputer 21 and the pre-driver IC 61 is, for example, SPI communication, a chip select terminal, a MISO terminal, a MOSI terminal, and the like are included.

The upper arm element of each phase is built in each of the three high-side chips 712, and the lower arm element of each phase is built in each of the three low-side chips 713. In addition, the current detection elements 517 to 519 are built in the low-side chip 713.

The three high-side chips 712 are disposed on the power land 722 which is a power supply potential, and the high-side chips 712 are disposed side by side so that the gate electrode faces the control chip 711 and is along the long side of the control chip 711. In the high-side chip 712, a source electrode faces upward, and a drain electrode provided on the back side is connected to the power land 722. On the upper side of the high-side chip 712, the intermediate clip 715, the low-side chip 713, and the ground clip 716 are stacked in this order from the high-side chip 712 to form a stack structure.

The intermediate clip 715 is, for example, a conductive metal plate made of copper or the like, and is provided for every three high-side chips 712. The intermediate clip 715 is connected to the source electrode of the high-side chip 712 at the lower face, and is connected to the drain electrode of the low-side chip 713 at the upper face. The intermediate clip 715 is disposed to be shifted to such an extent that a signal line 718 can be connected to the control chip 711 of the high-side chip 712. The end portion of the intermediate clip 715, the end portion being opposite to the control chip 711, is bent downward and connected to the output land 723. The output land 723 is connected to the motor terminal, and is connected to each phase of the motor winding 121 via the substrate wiring or the like.

Assuming that a direction in which high-side chips 712 are adjacent to each other is a width direction (in the figure, a “first direction”), the intermediate clip 715 is formed to be away from the adjacent frame in the width direction to such an extent that insulation can be ensured, and to be wider than the high-side chip 712. The area of the intermediate clip 715 is formed larger than that of the high-side chip 712. By forming the area of the intermediate clip 715 as large as possible, the heat dissipation efficiency is enhanced.

The ground clip 716 is a conductive plate made of copper or the like, for example, and is provided across the three low-side chips 713. The ground clip 716 is disposed to be shifted to such an extent that the signal line 718 can be connected at the control chip 711 side of the low-side chip 713. The ground clip 716 is bent downward on one side in the width direction and connected to the ground land 724. In the present embodiment, the ground clip 716 is provided in the sealing part 749, but the top face may be exposed from the sealing part 749.

The high-side chip 712 and the low-side chip 713 are connected to the control chip 711 by the signal line 718. In the present embodiment, although the high-side chip and the low-side chip are stacked, the high-side chip 712 and the low-side chip 713 are shifted from each other and stacked in a stepwise manner, and a non-overlapping region that does not overlap with a component provided on the upper side is ensured. Therefore, the signal line 718 can be connected in the non-overlapping region. The connection ends of the signal lines 718 on the control chip 711 side are aggregated on one side of the control chip 711. The signal lines 718 include those for gate driving, current detection, and temperature detection. As a result, the drive element region Rd to which a large current is applied and the IC region Ric can be spatially divided inside the driver component 701.

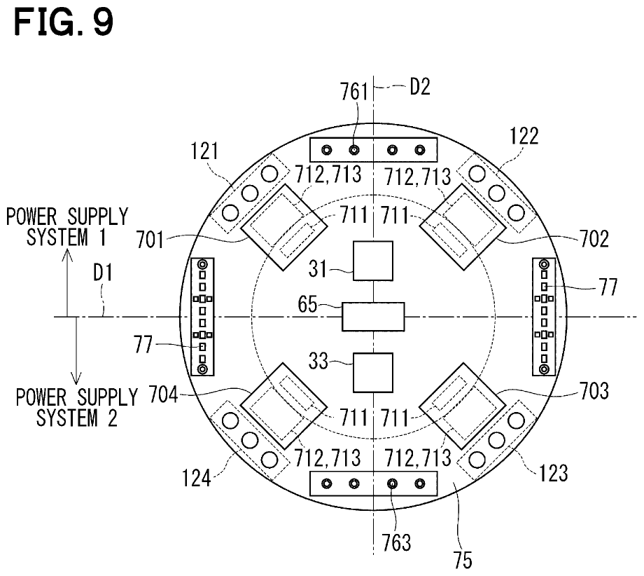

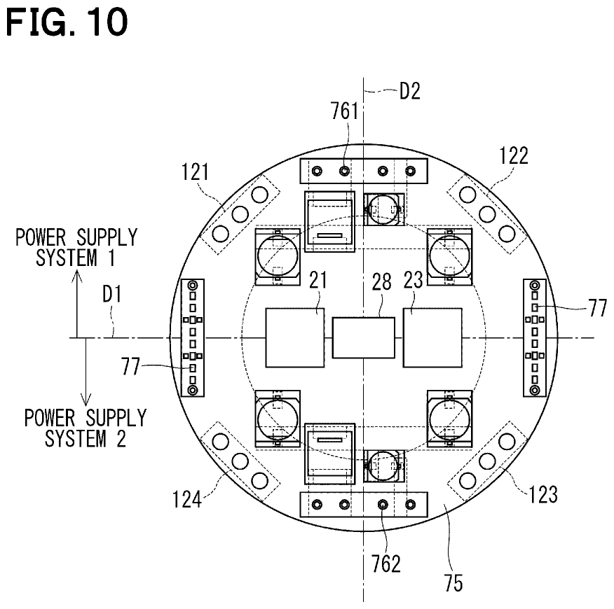

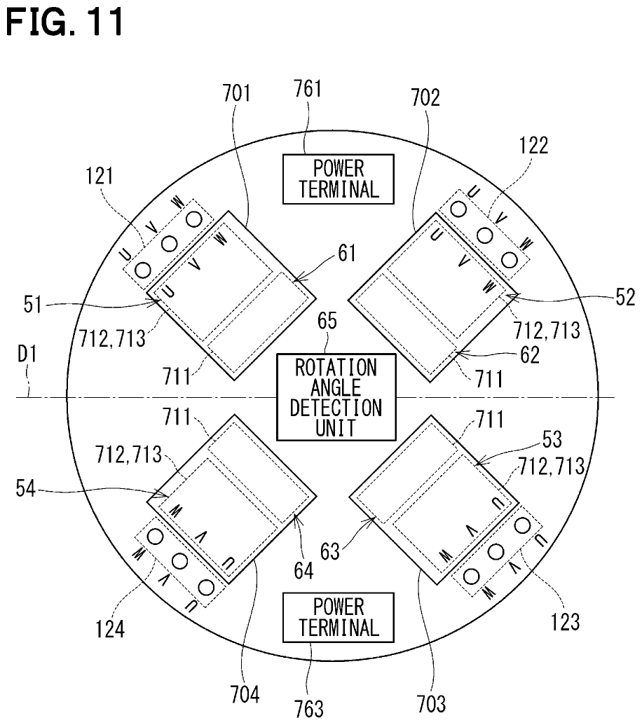

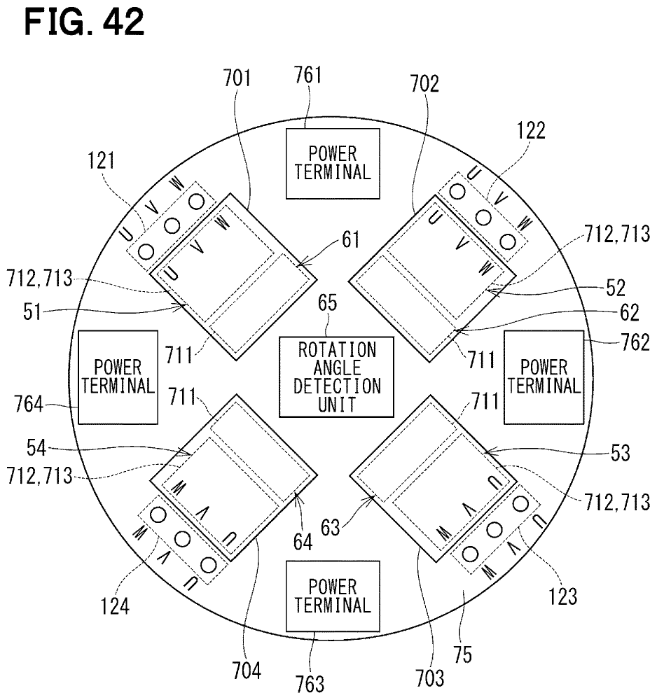

The component arrangement on the substrate 75 is illustrated in FIGS. 9 to 11. FIGS. 9 and 11 illustrate a face of the substrate 75, the face being close to the motor 11, and FIG. 10 illustrates a face of the substrate 75, the face being opposite to the motor 11. FIG. 11 schematically illustrates the arrangement of the driver components 701 to 704 and the motor windings 121 to 124 on the substrate 75. The same applies to FIG. 42 and the like.

As illustrated in FIGS. 9 and 11, the driver components 701 to 704 are mounted on the substrate 75. The four driver components 701 to 704 are provided on a face of the substrate 75, the face being close to the motor 11. The four driver components 701 to 704 are disposed on concentric circles at substantially equal intervals. The driver components 701 and 702 and the driver components 703 and 704 are disposed line-symmetrically with respect to a substrate division line D1. The substrate division line D1 is a division line that divides regions having different power supplies.

The driver components 701 to 704 are disposed so that the element side end portions face radially outward. The motor windings 121 to 124 are connected to the substrate 75 at the radially outer side of the driver components 701 to 704. That is, the control chip 711, the high-side chip 712 and the low-side chip 713, and the motor wire connection portion are disposed in this order from the radially inner side. The extraction wires of the motor windings 121 to 124 are disposed substantially parallel to the element-side end portions of the driver components 701 to 704 so as to correspond to the phase arrangement of the switching elements in the driver components 701 to 704. The phase arrangement illustrated in FIG. 11 is an example, and may be different. In FIGS. 9 to 11, the winding connection portions to which the extraction wires of the motor windings are connected are numbered as the motor windings 121 to 124. The same applies to the power terminal and the signal terminal.

On the face of the substrate 75, the face being close to the motor 11, a rotation detection unit 65 is mounted at a position facing a magnet provided at an end of a shaft (not illustrated) of the motor 11. In the present embodiment, the rotation detection unit 65 is mounted at the center of the substrate 75. The rotation detection unit 65 includes the position sensors 66 to 69.

The power terminals 761 and 763 are connected to a region at the outer edge of the substrate 75 and across a substrate center line D2 orthogonal to the substrate division line D1. Each of the power terminals 761 and 763 includes a power supply terminal and a ground terminal. Power from the power supply 501 is supplied to the power terminal 761, and power from the power supply 502 is supplied to the power terminal 763. On the substrate 75, the power supply ICs 31 and 33 are mounted between the rotation detection unit 65 and the power terminals 761 and 763 on the substrate center line D2. The power supply ICs 31 and 33 may be disposed at positions other than the substrate center line D2 as long as the power supply ICs 31 and 33 are easily connected to the power terminals 761 and 763 and the microcomputers 21 and 23. In addition, a signal terminal 77 is connected to a region at the outer edge of the substrate 75 and across the substrate division line D1.

As illustrated in FIG. 10, the microcomputers 21 and 23 are mounted on the face opposite to the motor 11, on both sides across the substrate center line D2 on the substrate division line D1. Power is supplied from the power terminal 761 to the microcomputer 21, and a wiring pattern is formed so that power is supplied from the power terminal 763 to the microcomputer 23. The microcomputers 21 and 23 are communicably connected, and the isolator 28 is mounted at a connection portion between the microcomputers 21 and 23. In the present embodiment, the isolator 28 is provided at the center of the substrate. The components such as a capacitor and a coil constituting a filter circuit are mounted on a face opposite to the motor 11.

In the present embodiment, the drive device 10 is applied to the electric power steering device 5. In a case where the drive device 10 is applied not only to the electric power steering device 5 but also to, for example, a main motor or a brake motor, various components may be made redundant so that safety can be secured even in a case where a failure occurs in some components.

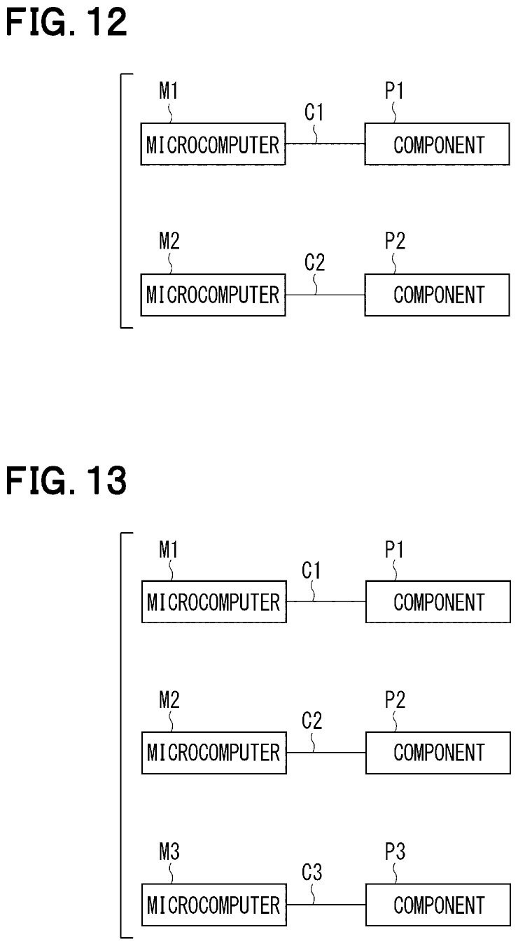

FIGS. 12 to 15 conceptually illustrate a communication configuration between the microcomputer and the component. As illustrated conceptually in FIG. 12, assuming that the combinations of the microcomputers (or the processing cores) M1 and M2 communicably connected by the communication lines C1 and C2 and the components P1 and P2 are the control systems, in a case where a failure occurs in the microcomputer M1 or the component P1 which is the first control system, the microcomputer M2 and the component P2 which are the second control system can continue to operate with 50% of the function remaining. Here, in a case where a failure occurs in any part of the second control system, the control cannot be continued.

As illustrated in FIG. 13, as further redundancy, for example, in a case where the three control systems are provided, it is possible to continue the operation with 66% of the function remaining in the first failure, and it is possible to continue the operation with 33% of the function remaining in the remaining one control system even in a case where the further failure occurs during the operation continuation in the first failure and the two control systems. However, when the number of control systems is increased, the number of components is increased.

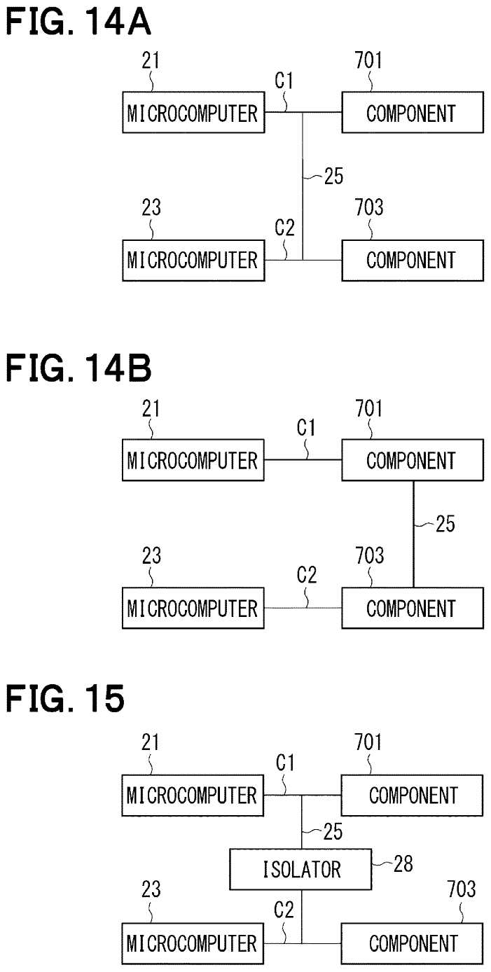

As illustrated in FIGS. 14A and 14B, the microcomputers M1 and M2 correspond to the microcomputers 21 and 23, respectively, and the components P1 and P2 correspond to the driver components 701 and 703, respectively. The driver components 701 and 703 include the pre-driver ICs 61 and 63 for controlling the driver circuits 51 and 53, and output drive signals for driving the driver circuits 51 and 53 according to commands transmitted from the microcomputers 21 and 23. Current detection values, driver outputs, abnormality information, temperature information, and the like are transmitted from the driver components 701 and 703 to the microcomputers 21 and 23.

As illustrated in FIG. 14A, in a case where the driver components 701 and 703 are capable of digital communication, the communication line C1 of the first system and the communication line C2 of the second system are connected to each other by the inter-system connection line 25, so that, for example, in a case where a failure occurs in the microcomputer 21, the microcomputer 23 commands the driver components 701 and 703. As a result, the control can be continued. When the second failure occurs in any one of the driver components 701 and 703, the control can be continued by the normal microcomputer and the normal driver component. As a result, even in the case of the two control systems, it is possible to increase the possibility of operation continuity at the time of failure. As illustrated in FIG. 14B, the inter-system connection line 25 may connect the driver components 701 and 703.

Communication between the microcomputers 21 and 23 and the components 701 and 703 is, for example, SPI communication, but may be a communication method other than SPI, such as PSI5, SENT, CAN, Ethernet, or Flexray, or may be wireless communication. Although one communication line is illustrated in FIG. 14A and the like, the number of communication lines and the number of terminals can be set in any number according to a communication method and the like.

As illustrated in FIG. 14A, in a case where the communication lines C1 and C2 are connected by the inter-system connection line 25, there is a failure mode in which all the connected microcomputers and components fail to operate in a case where the communication line is connected to the power supply or the ground and voltage is fixed. In addition, in a case where the microcomputers M1 and M2 are connected to different power supplies, there is a possibility of failure due to application of a high voltage to the normal system or inflow of a large current because of a failure of one control system.

Therefore, as illustrated in FIG. 15, the isolator 28 as a system separation component is provided at a location where it is not desired to cause simultaneous failures. Note that the description of the isolator 28 is omitted in FIG. 2 and the like. In the example of FIG. 15, the isolator 28 is provided in the inter-system connection line 25, but may be provided inside the microcomputers M1 and M2 or the components P1 and P2, for example. As a configuration for separating the systems, it is sufficient that information can be transmitted while a potential difference is maintained, and the system separation component may be provided with, for example, a passive element such as a resistor, a buffer, or the like instead of the isolator. In addition, by using wireless communication as the communication, a tailgating failure may not occur.

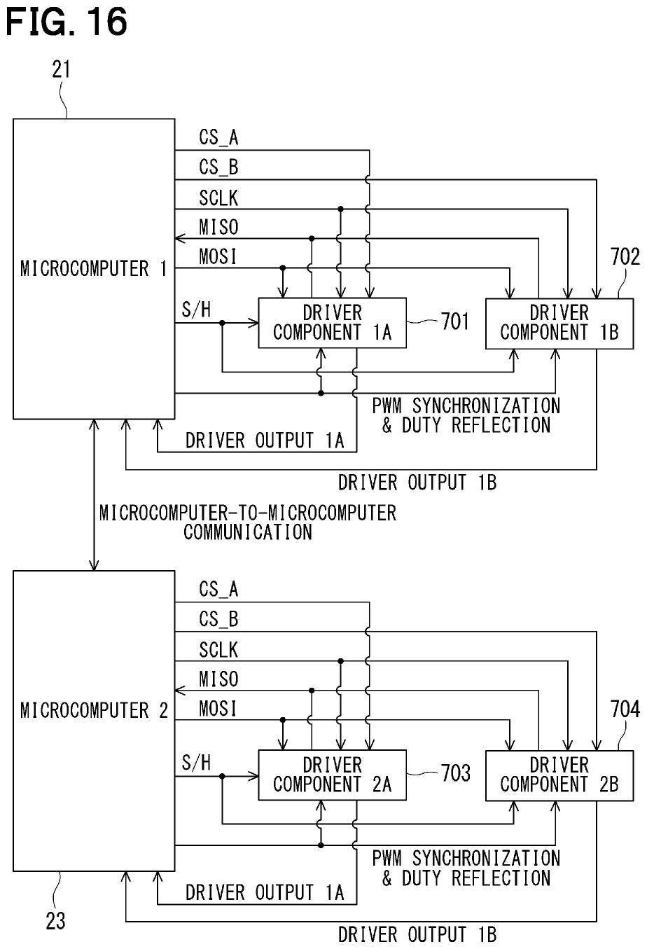

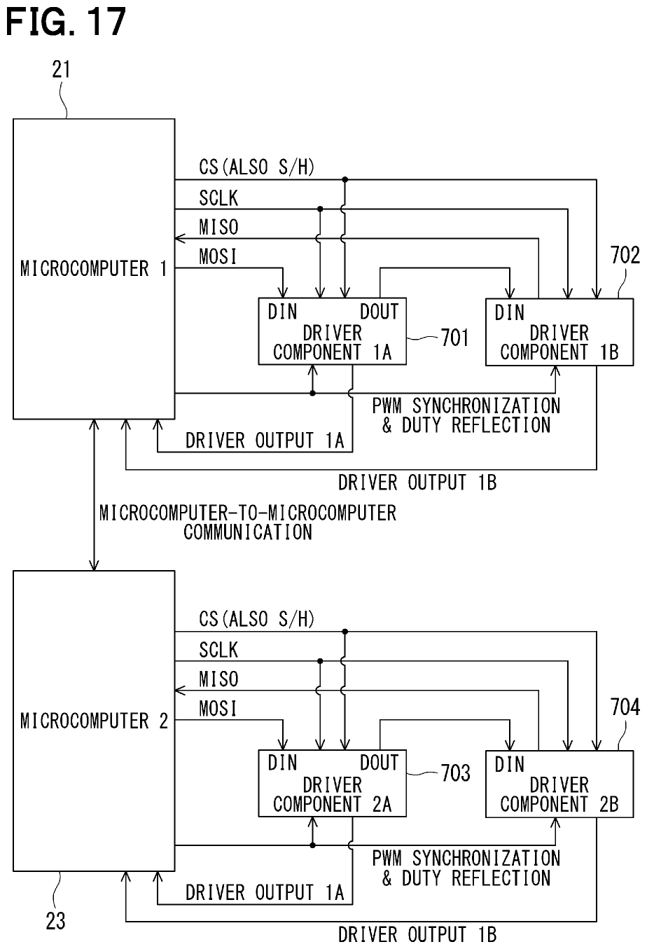

Specific examples of the communication configuration are illustrated in FIGS. 16 and 17. In FIGS. 16 and 17, for the sake of simplicity, the signal lines of the two cores of each microcomputer are collectively illustrated, and the inter-system connection line is omitted. As illustrated in FIG. 16, the microcomputers 21 and 23 can transmit the common clock signal SCLK and MOSI signal to the driver components 701 to 704 provided correspondingly, and can transmit the chip select signal CS_A to the driver components 701 and 703 and the chip select signal CS_B to the driver components 702 and 704. The driver components 701 to 704 can transmit the MISO signal to the microcomputers 21 and 23 provided correspondingly.

The microcomputers 21 and 23 are provided to be microcomputer-to-microcomputer communicable, and perform PWM synchronization, duty update timing synchronization, and sample and hold timing synchronization on the four driver components 701 to 704. The microcomputers 21 and 23 check the PWM update using the PWM reflection value and the current detection value based on the MISO signal. The PWM update may be checked by returning the driver output from the driver components 701 to 704 to the microcomputers 21 and 23. In a case where the driver output is not returned to the microcomputers 21 and 23, terminals and wires for returning the driver output can be omitted.

As illustrated in FIG. 17, the microcomputer 21, the driver component 701, and the driver component 702 may be a so-called “daisy-chain connection” that annularly connects the communication lines. Similarly, the microcomputer 23, the driver component 703, and the driver component 704 may be daisy-chain connected.

Specifically, signals from the microcomputers 21 and 23 are transmitted to the driver components 701 and 703, and the signals are transmitted from the driver components 701 and 703 to the driver components 702 and 704. The driver components 702 and 704 transmit MISO signals to the microcomputers 21 and 23, for example. In this case, the chip select signal and the sample hold may be common. Accordingly, the number of terminals and the number of wirings can be reduced.

In the present embodiment, since the communication lines of the control systems are connected by the inter-system connection line 25, the microcomputers 21 and 23 do not issue commands when communication from another microcomputer starts, or output commands after a predetermined time elapses after responses from the driver components 701 and 703 so that data is not mixed on the communication lines. In addition, the command destination may be identified by chip selection, ID assignment, or the like for the command from the microcomputers 21 and 23.

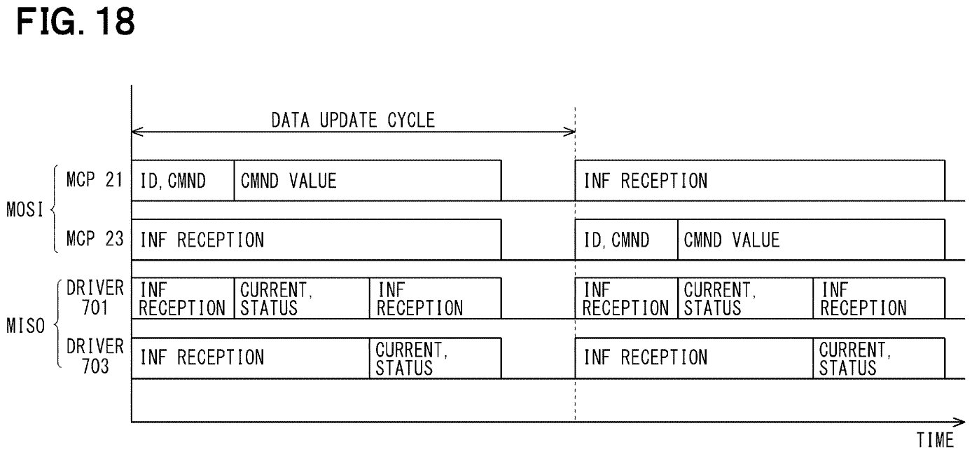

FIG. 18 illustrates an example of data transmission/reception. In the present embodiment, an ID and a command are output from each of the microcomputers 21 and 23 to designate a component to be driven. For example, a component to be driven is designated by the ID, and the MOSI transmits a current command value and an on-duty to the component. In the ID system, a component to be driven is designated by an ID, but an ID for simultaneously issuing commands to a plurality of components can also be set. Thus, for example, the timings of current detection of the plurality of components can be aligned. The component to be driven may be designated by a chip selection method.

The driver components 701 and 703 transmit current values and status information to the microcomputers 21 and 23, respectively. Since the data transmission from the driver components 701 and 703 is performed by the MISO, the information can be transmitted even during the command transmission from the microcomputers 21 and 23. However, for example, the transmission from the driver component 703 is set to start when the transmission from the driver component 701 is completed so that the data transmission timings from the different driver components do not overlap. In addition, for example, data arbitration may be performed by setting transmission in order of ID.

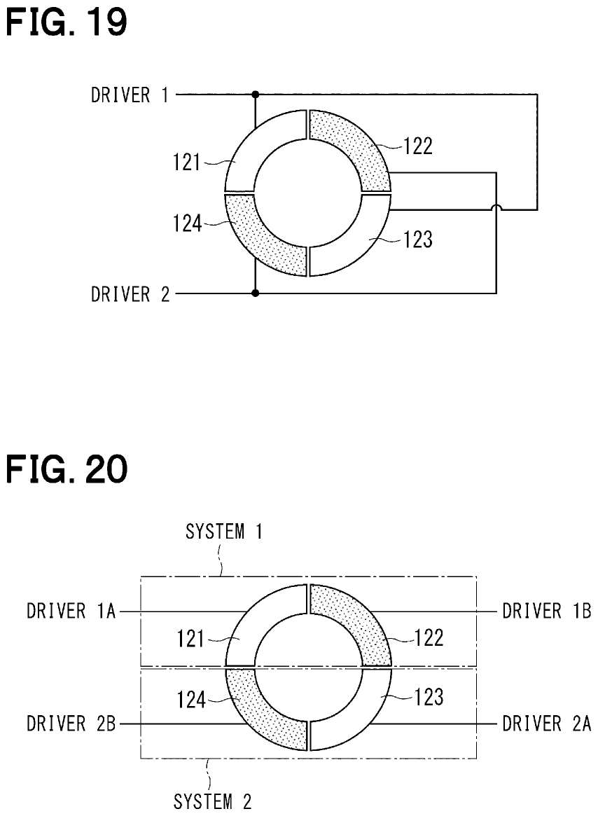

FIGS. 19 and 20 schematically illustrate an arrangement of motor windings, and three-phase wirings are indicated by one line. In the concentrated winding motor, a stator has a plurality of windings, and a three-phase motor having three input terminals is formed by connecting the plurality of windings. Depending on how the windings are connected, a set of three-phase windings can be configured, or a plurality of sets of three-phase windings can be configured. FIG. 19 illustrates an example of a case where two sets of three-phase windings are configured, and in a case where the windings facing each other at 180° are connected, the configuration of the wiring related to the connection of the plurality of windings and the bus bar responsible for the wiring tends to be complicated.

In the present embodiment, two power supplies and four motor windings are configured. As illustrated in FIG. 20, for example, in a case where four sets of three-phase windings are configured by a concentrated winding motor using a stator having 14 poles 18 slots, 10 poles 12 slots, or 8 poles 12 slots, it is not necessary to connect the windings disposed facing each other, so that the wiring can be simplified.

In the present embodiment, the substrate 75 is provided on one side of the motor 11 in the axial direction, and the configurations corresponding to respective power supplies are collectively disposed in the regions divided by the substrate division line D1 (see FIGS. 1 and 9 to 11). In addition, four sets of motor windings 121 to 124 are allocated to the two power supplies 501 and 502 and the two microcomputers 21 and 23. In a case where the motor 11 is driven by four sets of motor windings 121 to 124, winding sets facing each other at 180° are often driven in the same phase. In a case where the winding sets driven in the same phase are allocated to the same power supply, there is a possibility that an increase in size due to complication of members for collecting wirings, deterioration in layout property due to a cross arrangement of wirings on the substrate 75, and a common cause failure due to a wiring short will occur.

Therefore, windings disposed adjacent to each other in the stator and having different drive phases are allocated to one power supply system. Specifically, power is supplied from the power supply 501 to the windings 121 and 122, and power is supplied from the power supply 502 to the windings 123 and 124. In the present embodiment, since the inter-system connection line 25 is provided, a command to a winding allocated to another power supply can also be output by one core. Therefore, even when two windings disposed adjacent to each other in the stator and having different drive phases are allocated to the same power supply and disposed, the driver driving in the same phase can be operated by a command from the same core.

In addition, since the energization phases of the windings allocated to the same power supply are different, the timing at which the pull-in current is maximized when the motor is driven is shifted. As a result, as compared with a case where the driver circuit driven in the same phase is allocated to the same power supply, the power consumption in the driver circuit can be smoothed, and for example, the smoothing capacitor can be downsized. In addition, it is possible to integrate components allocated to the same power supply system to one side of the substrate, improve layout, and reduce the occurrence of common cause failures due to wiring short-circuiting. In FIG. 20, the windings 121 and 123 energized in the same phase are indicated by white, and the windings 122 and 124 energized in the same phase at a phase different from that of the windings 121 and 123 are indicated by satin.

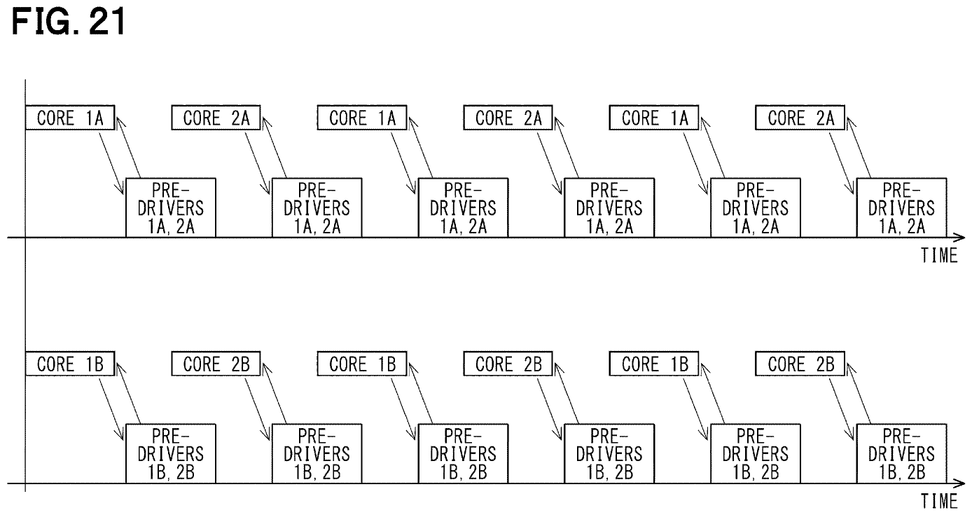

The communication between the processing cores 211, 212, 231, and 232 and the pre-driver ICs 61 to 64 will be described with reference to FIG. 21. In the description of communication, for the sake of simplicity, the processing core 211 is referred to as a “core 1A”, the processing core 212 as a “core 1B”, the processing core 231 as a “core 2A”, the processing core 232 as a “core 2B”, the pre-driver IC 61 as a “pre-driver 1A”, the pre-driver IC 62 as a “pre-driver 1B”, the pre-driver IC 63 as a “pre-driver 2A”, and the pre-driver IC 64 as a “pre-driver 2B”.

In the present embodiment, the windings 121 and 123 provided corresponding to the pre-drivers 1A and 2A face each other and are wound around the stator, and are energized in the same phase. The windings 122 and 124 provided corresponding to the pre-drivers 1B and 2B face each other and are wound around the stator, and are energized in the same phase. The energization phases of the windings 121 and 123 are different from the energization phases of the windings 122 and 124. It is assumed that the amplitudes of the currents applied to the windings 121 to 124 are the same.

As illustrated in FIG. 21, the cores 1A and 2A transmit command signals such as a duty command value and various drive permission signals to the pre-drivers 1A and 2A driven in the same phase. The pre-drivers 1A and 2A transmit current detection values and status information (for example, driver output, abnormality information, temperature information, and the like) to the cores 1A and 2A. In addition, the cores 1B and 2B transmit command signals such as a duty command value and various drive permission signals to the pre-drivers 1B and 2B driven in the same phase. The pre-drivers 1B and 2B transmit current detection values and status information to the cores 1B and 2B.

In the present embodiment, the cores 1A and 2A transmit drive commands to the pre-drivers 1A and 2A, but do not transmit drive commands to the pre-drivers 1B and 2B. Here, the pre-drivers 1B and 2B may transmit the current detection values and the status information to the cores 1A and 2A that have not received the drive command. Similarly, the pre-drivers 1A and 2A may transmit the current detection value and the status information to the cores 1B and 2B that have not received the drive command. As a result, each core can grasp the control state of the entire drive device 10.

The cores 1A and 2A alternately transmit commands to the pre-drivers 1A and 2A. Similarly, the cores 1B and 2B alternately transmit commands to the pre-drivers 1B and 2B. As a result, the processing load of each core can be reduced.

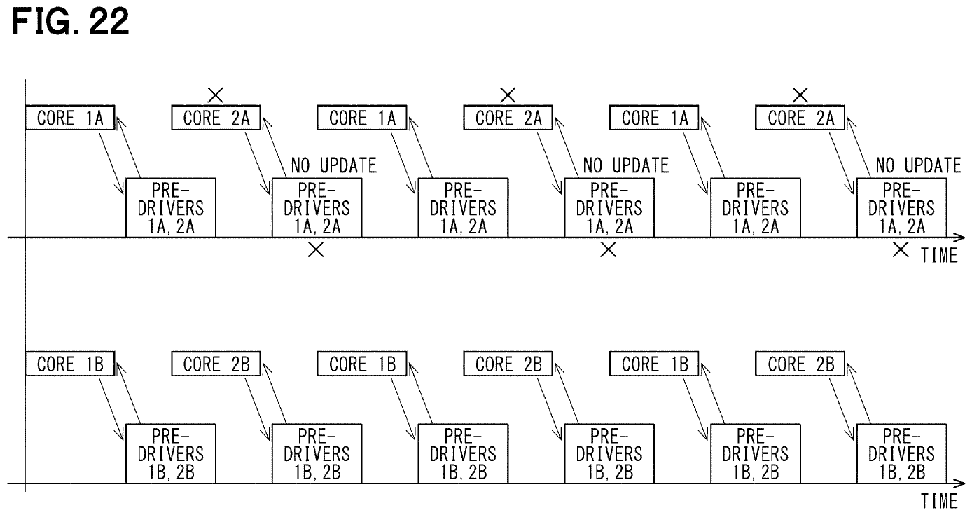

As illustrated in FIG. 22, in a case where one core fails, even in a case where the processing is not changed from that in a normal operation, the control is continued without causing a fatal influence although the update cycle is extended. Specifically, for example, in a case where the core 2A fails, the information at the update timing of the command of the core 2A is not updated in the A group, and the update cycle is extended. In this case, the previous command value is held for the update timing in the core 2A. The influence of the failure can be reduced by using the estimated value from the past data at the update timing in the core 2A.

At the command update timing in the failed core 2A, the command may be transmitted from the normal core 1A instead of from the core 2A. As a result, it is possible to prevent performance degradation including the update cycle. In addition, the pre-drivers 1B and 2B that do not use the command of the core 2A can continue the control without being affected by the failure of the core 2A.

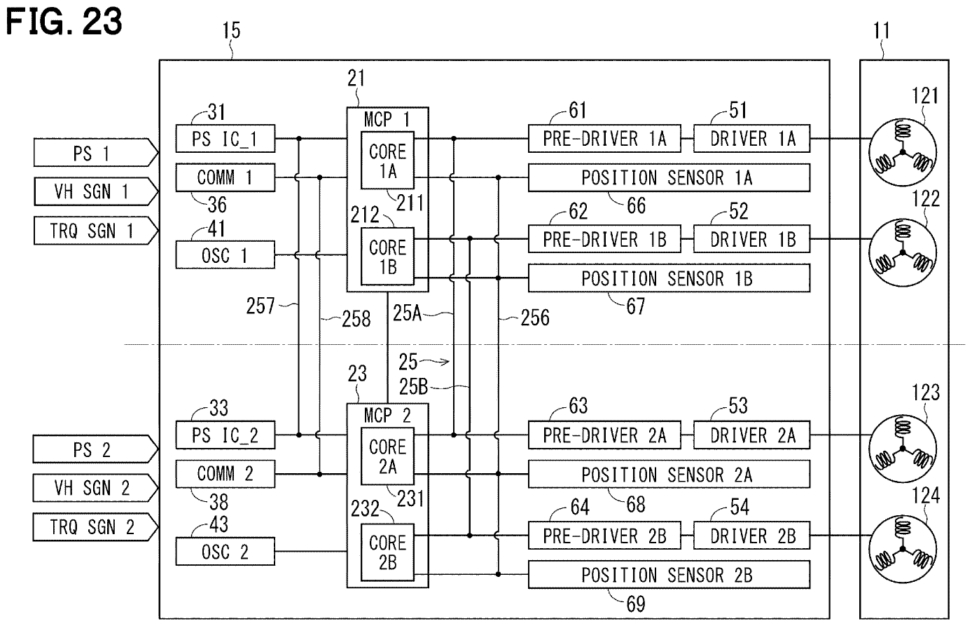

As illustrated in FIG. 23, the inter-system connection line 25 may be divided into the A group and the B group that are driven in the same phase. In FIG. 23, the inter-system connection line of the A group is “25A”, and the inter-system connection line of the B group is “25B”. By dividing the communication line for each phase, the amount of information of the communication line can be suppressed. In addition, since the common failure mode in the communication line can be avoided, even in a case where an abnormality occurs in one of the communication lines, the control can be continued.

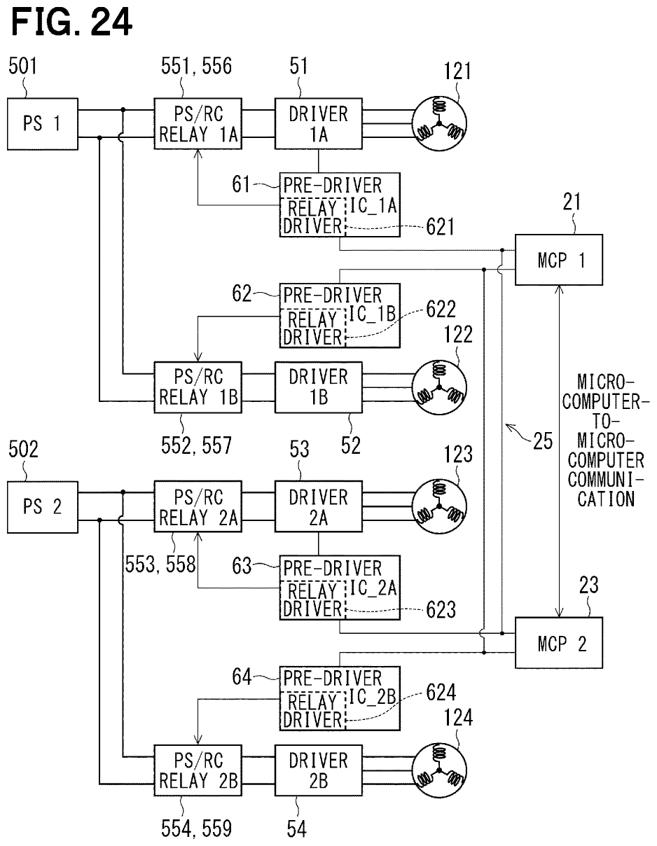

Next, driving of the power supply relay and the reverse connection protection relay will be described. As illustrated in FIG. 24, in the present embodiment, the power supply relays 551 to 554 and the reverse connection protection relays 556 to 559 are provided for respective driver circuits 51 to 54, and are driven in response to individual commands from the relay driver circuits 621 to 624 of the corresponding driver circuits 51 to 54 in the normal operation. In FIG. 24, the power supply relay and the reverse connection protection relay are collectively referred to as a “power supply/reverse connection relay”, and the description of the processing core in the microcomputer is omitted. In FIG. 24, the inter-system connection lines are divided into the A group and the B group as illustrated in FIG. 23, but the inter-system connection lines may be integrated as illustrated in FIG. 2.

In a case where an abnormality occurs in the pre-driver IC 61, the power supply relay 551, or the reverse connection protection relay 556, the pre-driver IC 61 is configured to be pulled down (off), and the other pre-driver ICs 62 to 64 do not perform driving. The same applies to a case where an abnormality occurs in another pre-driver IC, another power supply relay, another reverse connection protection relay, or another motor relay (not illustrated in FIG. 24).

In a case where an abnormality occurs in the microcomputer 21, the microcomputer 23 commands the relay driver circuits 621 and 622 in the pre-driver ICs 61 and 62 to drive the power supply relays 551 and 552 and the reverse connection protection relays 556 and 557. Similarly, in a case where an abnormality occurs in the microcomputer 23, the microcomputer 21 commands the relay driver circuits 623 and 624 in the pre-driver ICs 63 and 64 to drive the power supply relays 553 and 554 and the reverse connection protection relays 558 and 559. As a result, even in a case where an abnormality occurs in one of the microcomputers, the motor 11 can be continuously driven by relay driving according to a command from another microcomputer.

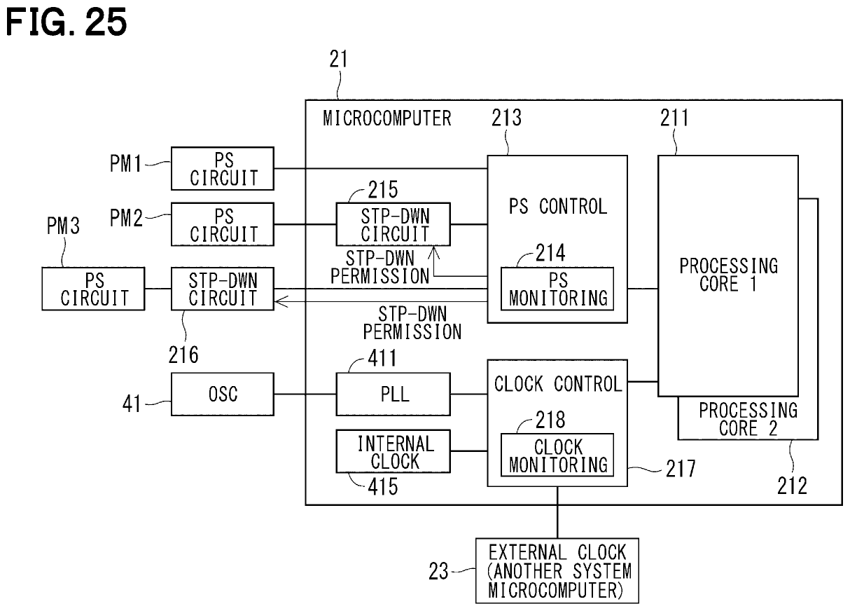

Next, a redundant configuration in the microcomputer will be described with reference to FIG. 25. Here, the microcomputer 21 will be described as an example. The microcomputer 21 includes processing cores 211 and 212, a power supply control unit 213, a clock control unit 217, and the like.

The power supply control unit 213 includes a power supply monitoring unit 214. The power supply control unit 213 is connected to a plurality of power supply circuits PM1 to PM3. The power supply circuits PM1 and PM2 correspond to the power supply IC 31, and the power supply circuit PM3 corresponds to the power supply IC 33. The power supply IC 31 has, for example, a core power supply voltage output (for example, about 1.2 [V]) and a power supply output (for example, 5 [V]) different from the core power supply voltage, and the core power supply corresponds to the power supply circuit PM1, and the 5 V power supply corresponds to the power supply circuit PM2. The power supply circuits PM1 and PM2 correspond to the same power supply IC 31, and generate different voltages inside the power supply IC 31, and can be regarded as “different power supply sources”. That is, it can be said that the power supply control unit 213 of the present embodiment has a redundant configuration in which power is supplied from three different power supply sources.

The voltage generated by the power supply circuit PM1 is input as it is to the power supply control unit 213 and used by the processing cores 211 and 212. The power from the power supply circuit PM2 is stepped down by an internal step-down circuit 215 and input to the power supply control unit 213 to be used for core processing. The power from the power supply circuit PM3 is stepped down by a step-down circuit 216 outside the microcomputer and input to the power supply control unit 213. Note that the power supply circuit PM2 may be supplied with power from a power supply different from the power supply IC 33, such as the power supply IC 31, or may be configured to be stepped down by a step-down circuit outside the microcomputer. The power supply monitoring unit 214 monitors the voltage supplied from each power supply circuit.

The clock control unit 217 includes a clock monitoring unit 218. The clock control unit 217 acquires a clock signal from an oscillator 41 via a phase-locked loop (PLL) 411. Furthermore, the clock control unit 217 acquires a clock signal from an internal clock circuit 415 and an external clock circuit. In the present embodiment, the external clock circuit is the microcomputer 23 of another system, and acquires a clock signal from the microcomputer 23. The external clock circuit is not limited to another system microcomputer, and may be a clock circuit separately provided.

That is, it can be said that the clock control unit 217 of the present embodiment has a redundant configuration in which clocks are supplied from three different clock sources. Hereinafter, the clock signal acquired from the oscillator 41 via the phase-locked loop 411 is referred to as a “PLL clock”, the clock signal acquired from the internal clock circuit 219 is referred to as an “internal clock”, and the clock signal acquired from the external clock circuit is referred to as an “external clock”.

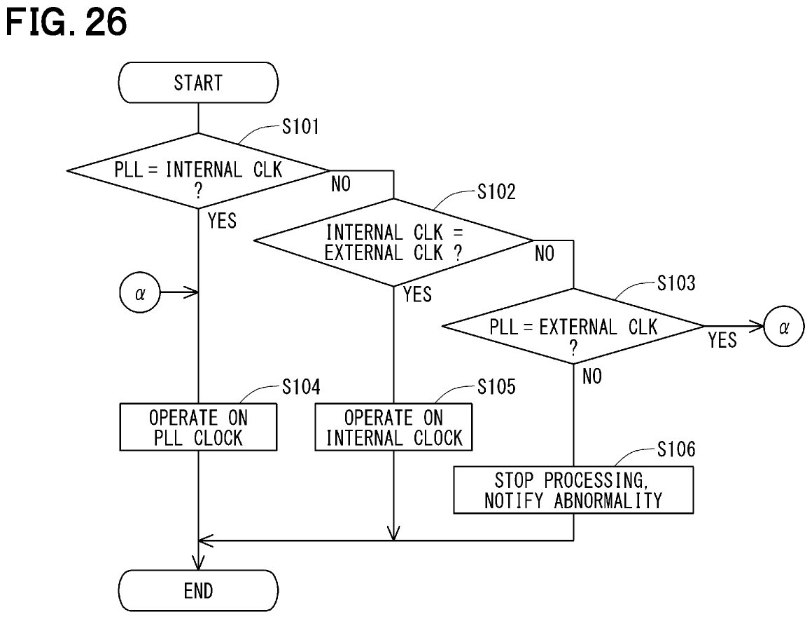

The clock monitoring process of the present embodiment will be described with reference to the flowchart of FIG. 26. Here, although the process in the microcomputer 21 will be described, the similar process is performed in the microcomputer 23. Each process in the microcomputers 21 and 23 may be software processing by executing a program stored in advance in a tangible memory device (that is, a readable non-transitory tangible recording medium) such as a ROM by a CPU, or may be hardware processing by a dedicated electronic circuit. Hereinafter, “step” such as step S101 is omitted, and is simply referred to as a symbol “S”.

In S101, the clock monitoring unit 218 determines whether the PLL clock and the internal clock match. Note that a deviation of an allowable error range is permitted, and it is determined that the PLL clock and the internal clock match. The same applies to another match determination. In a case where it is determined that the PLL clock and the internal clock match (S101: YES), the process proceeds to S104. In a case where it is determined that the PLL clock and the internal clock do not match (S101: NO), the process proceeds to S102.

In S102, the clock monitoring unit 218 determines whether the internal clock and the external clock match. In a case where it is determined that the internal clock and the external clock match (S102: YES), the process proceeds to S105. In a case where it is determined that the internal clock and the external clock do not match (S102: NO), the process proceeds to S103.

In S103, the clock monitoring unit 218 determines whether the PLL clock matches the external clock. In a case where it is determined that the PLL clock matches the external clock (S103: YES), the process proceeds to S104. In a case where it is determined that the PLL clock and the external clock do not match (S103: NO), the process proceeds to S106.

In S104 to which the process proceeds in a case where the PLL clock matches the internal clock or the external clock, the clock control unit 217 operates the processing cores 211 and 212 using the PLL clock.

In S105 to which the process proceeds in a case where the PLL clock and the internal clock do not match and the internal clock and the external clock match, the clock control unit 217 operates the processing cores 211 and 212 using the internal clock. That is, the PLL clock is used in the normal state, but the PLL clock is switched to the internal clock as the backup clock when the PLL clock is in the abnormal state. At this time, the switched clock is output to the microcomputer of another control system, and the processing is performed in synchronization with the clock received by another system microcomputer. In addition, abnormality monitoring by comparison between the internal clock and the external clock is continued.

In S106 to which the process proceeds in a case where none of the PLL clock, the internal clock, and the external clock match, the clock control unit 217 stops the processing of the processing cores 211 and 212 and notifies the external IC of the clock abnormality.

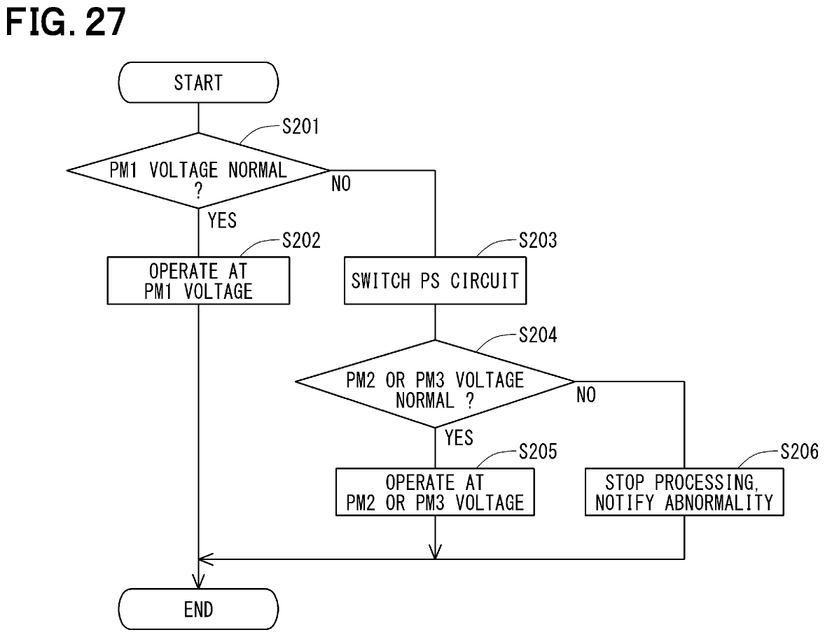

The power supply monitoring process will be described with reference to the flowchart of FIG. 27. In S201, the power supply monitoring unit 214 determines whether the core power supply voltage supplied from the power supply circuit PM1 is normal. In a case where it is determined that the core power supply voltage from the power supply circuit PM1 is normal (S201: YES), the process proceeds to S202, and the processing cores 211 and 212 are operated with the core power supply voltage from the power supply circuit PM1. In a case where it is determined that the core power supply from the power supply circuit PM1 is not normal (S201: NO), the process proceeds to S203, and the power supply used for the core processing is switched from the power supply circuit PM1 to the power supply circuit PM2 or the power supply circuit PM3. Here, a case of switching to the power supply circuit PM2 as the backup power supply source will be described as an example. In the case of switching to the power supply circuit PM3, the power supply circuit PM2 may be replaced with the power supply circuit PM3, and thus the description thereof will be omitted.

In S204, the power supply monitoring unit 214 determines whether the core power supply voltage supplied from the power supply circuit PM2 via the step-down circuit is normal. In a case where it is determined that the core power supply voltage derived from the power supply circuit PM2 is normal (S204: YES), the process proceeds to S205, and the processing cores 211 and 212 are operated with the core power supply voltage derived from the power supply circuit PM2. In a case where it is determined that the core power supply voltage derived from the power supply circuit PM2 is not normal (S204: NO), the process proceeds to S206, the processing of the processing cores 211 and 212 is stopped, and the abnormality of the core power supply voltage is notified to the external IC. As a result, even in a case where a core power supply abnormality occurs in the power supply circuit PM1, the operation of the processing cores 211 and 212 can be continued by using the power supply circuits PM2 and PM3 as backup core power supplies.

As described above, the ECU 15 drives the motor 11 having the plurality of motor windings 121 to 124. The ECU 15 includes the plurality of driver components 701 to 704 and the substrate 75. The driver components 701 to 704 include the high-side chips 712 incorporating the switching elements 511 to 513, 521 to 523 as the upper arm elements connected to the high potential side, the low-side chips 713 incorporating the switching elements 514 to 516, 524 to 526 as the lower arm elements connected to the low potential side of the upper arm elements, and the control chips 711. The control chips 711 incorporate the pre-driver ICs 61 to 64 that output the drive signals to the upper arm elements and the lower arm elements. The driver components 701 to 704 are mounted on the substrate 75.

The driver components 701 to 704 are arranged on the substrate 75 in respective regions divided for components related to energization control of the respective motor windings, and the control chip 711, the high-side chip 712 and the low-side chip 713, and the motor wire connection portion to which the motor winding 121 to 124 is connected are arrayed in this order from one side. In the present embodiment, on the substrate 75, the control chip 711, the high-side chip 712 and the low-side chip 713, and the motor wire connection portion are arrayed in this order from the radially inner side. Since the driver components 701 to 704 are arranged so that the end on the element side is adjacent to the motor wire connection portion, the substrate wirings between the driver components 701 to 704 and the motor windings 121 to 124 can be simplified.

The low-side chip 713 is stacked on the corresponding high-side chip 712 in shifted manner so that a part of the high-side chip 712 is not overlapped by the low-side chip 713. Further, the control chip 711 is integrally sealed with the high-side chip 712 and the low-side chip 713 by the sealing part 749. Thus, the driver components 701 to 704 can be reduced in size.

The substrate 75 is supplied with the electric power from the plurality of power supplies 501 and 502. The ECU 15 has the isolator 28 at a location that connects the components provided in regions having different power supplies. In the present embodiment, “the location that connects the components provided in regions having different power supplies” is the inter-system connection line 25 that connects the communication lines connecting the microcomputers and the driver circuits over the regions having the different power supplies. Further, the isolator 28 can be arranged at a location other than the inter-system communication line, such as between the microcomputers, as long as it connects between the components having different power supplies. This allows appropriate connection even when the potentials of the power supply regions are different. In addition, when an abnormality occurs in a part of the power supply regions, simultaneous failure due to application of high voltage or inflow of current can be prevented.

### Second Embodiment, Third Embodiment

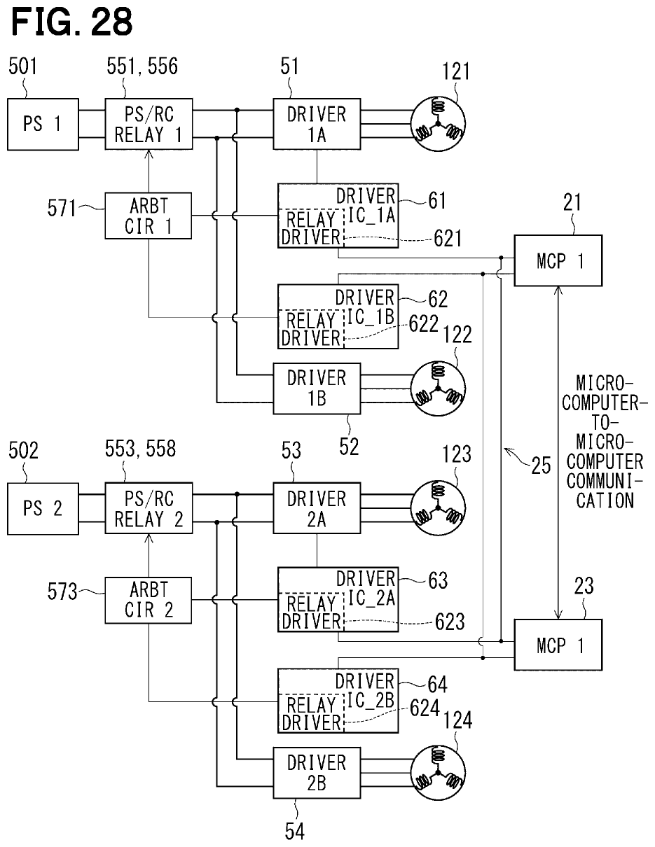

FIG. 28 illustrates a second embodiment. FIG. 28 is a diagram corresponding to FIG. 24 of the first embodiment, and the power supply relay and the reverse connection protection relay are different from those of the above embodiment. In the present embodiment, the power supply relays 551 and 553 and the reverse connection protection relays 556 and 558 are provided for each power supply. The power supply relay 551 and the reverse connection protection relay 556 are shared by the driver circuits 51 and 52, and the power supply relay 553 and the reverse connection protection relay 558 are shared by the driver circuits 53 and 54.

The relay driver circuits 621 and 622 drive the power supply relay 551 and the reverse connection protection relay 556 via an arbitration circuit 571. The relay driver circuits 623 and 624 drive the power supply relay 553 and the reverse connection protection relay 558 via an arbitration circuit 573. The number of relays can be reduced by providing the arbitration circuits 571 and 573.

In the normal state, the arbitration circuit 571 receives the same command from the relay driver circuits 621 and 622, performs matching, and drives the power supply relay 551 and the reverse connection protection relay 556. In a case where one of the relay driver circuits 621 and 622 is abnormal, the arbitration circuit 571 drives the power supply relay 551 and the reverse connection protection relay 556 by giving priority to a signal from a normally operating circuit because signals received from the relay driver circuits 621 and 622 are different.

In the normal state, the arbitration circuit 573 receives the same command from the relay driver circuits 623 and 624, performs matching, and drives the power supply relay 553 and the reverse connection protection relay 558. In a case where one of the relay driver circuits 623 and 624 is abnormal, the arbitration circuit 573 drives the power supply relay 553 and the reverse connection protection relay 558 by giving priority to a signal from a normally operating circuit because signals received from the relay driver circuits 623 and 624 are different.

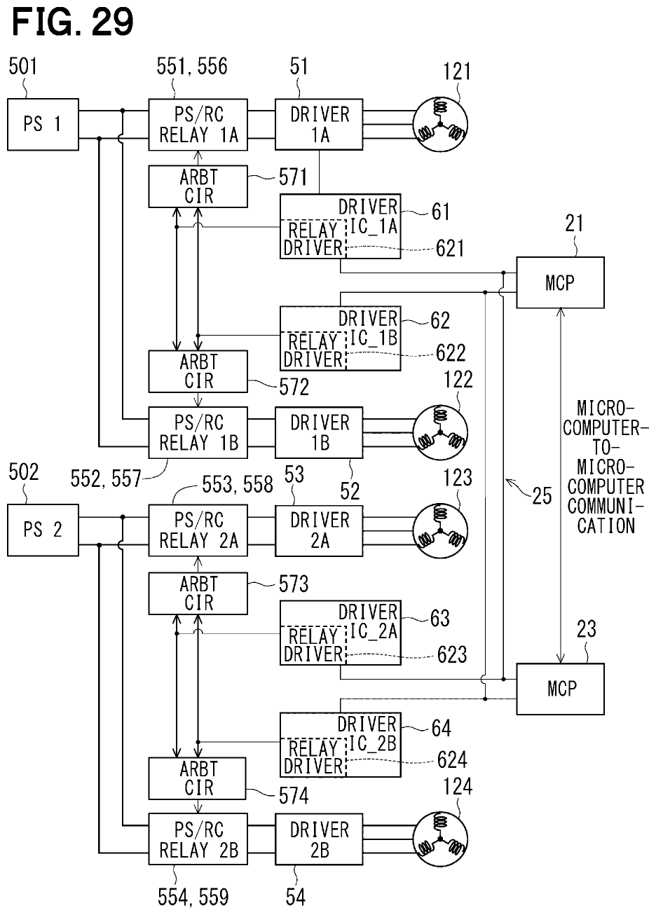

FIG. 29 illustrates a third embodiment. In the present embodiment, the power supply relays 551 to 554 and the reverse connection protection relays 556 to 559 are provided for the respective driver circuits 51 to 54, and in addition, the arbitration circuits 571 to 574 are provided.

The arbitration circuit 571 receives commands from the relay driver circuits 621 and 622, and drives the power supply relay 551 and the reverse connection protection relay 556. The arbitration circuit 572 receives commands from the relay driver circuits 621 and 622, and drives the power supply relay 552 and the reverse connection protection relay 557. The arbitration circuit 573 receives commands from the relay driver circuits 623 and 624, and drives the power supply relay 553 and the reverse connection protection relay 558. The arbitration circuit 574 receives commands from the relay driver circuits 623 and 624, and drives the power supply relay 554 and the reverse connection protection relay 559. The operation of the arbitration circuit 571 to 574 is substantially similar to that of the second embodiment. As a result, the operation of the motor 11 can be continued even in a wider failure mode. Further, the same effects as those of the above embodiment are obtained.

### Fourth Embodiment to Eighth Embodiment

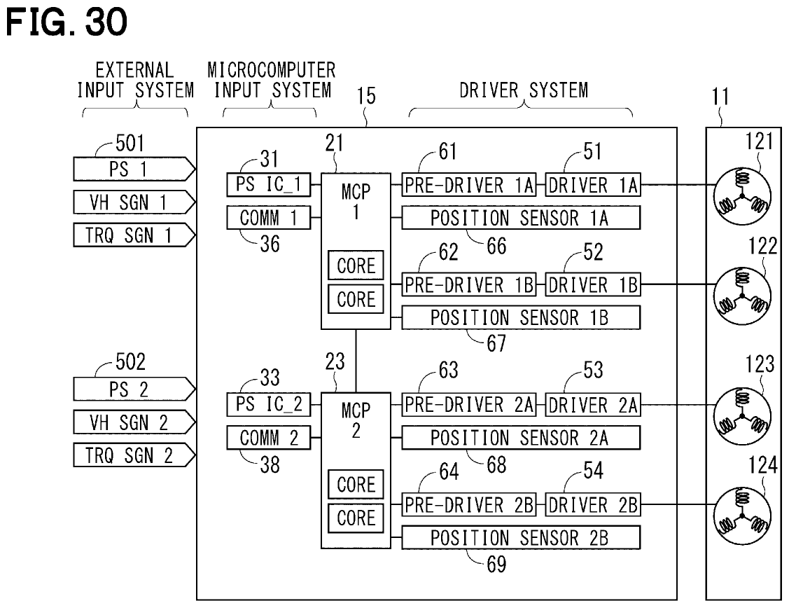

A fourth embodiment to an eighth embodiment are variations of the redundant configuration. In the description of the redundant system, the power supply, the vehicle signal input, and the torque signal input are collectively referred to as an “external input system”, the power supply IC, the communication unit, and the oscillator are collectively referred to as a “microcomputer input system”, and the pre-driver IC and the driver circuit are collectively referred to as a “driver system” as appropriate. The external input system corresponds to an input from the connector 16. In addition, the oscillator and the inter-system connection line are appropriately omitted. FIG. 30 illustrates a simplified configuration of the first embodiment. In a case where the number of cores in the microcomputer is not mentioned, the microcomputer has one processing core with a lockstep.

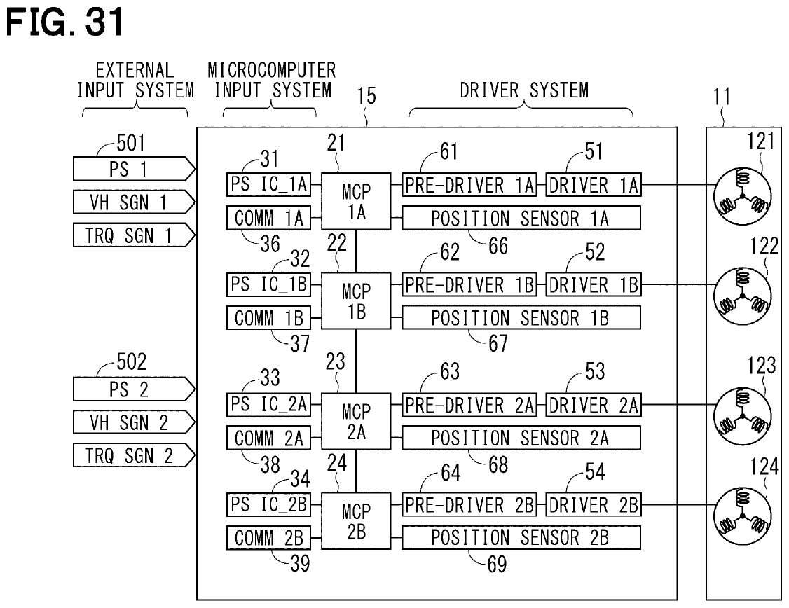

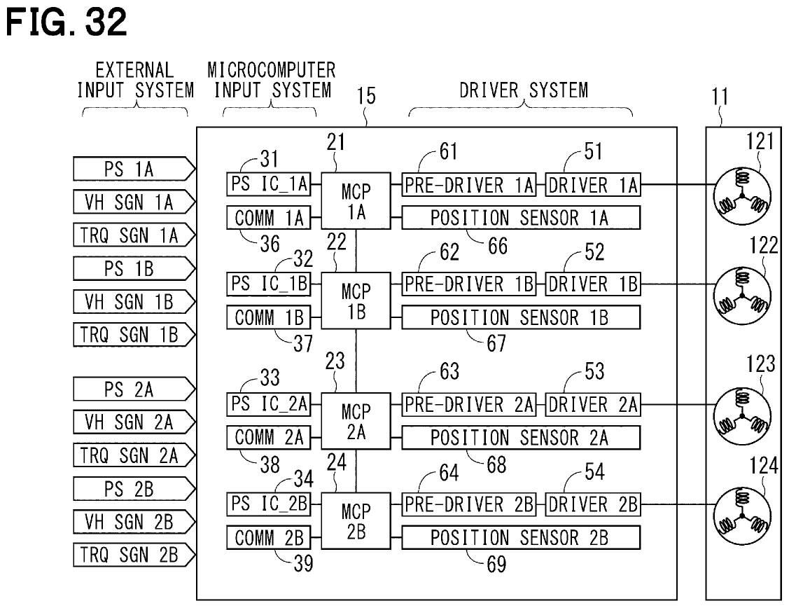

As illustrated in FIG. 31, in the fourth embodiment, the four microcomputers each having one processing core with a lockstep are provided. Other configurations are substantially the same as those of the first embodiment. As illustrated in FIG. 32, in the fifth embodiment, four external input systems are provided, and the power supply, the microcomputer, the driver, and the motor winding are provided for each of the four systems. By providing the power supply, the microcomputer, and the driver for each of the four systems, it is easy to combine with motors of the four systems. In addition, in the case of the two power supply configuration, it is easy to divide the power supply into two systems.

For all components, three or more of each component are provided, so that even when two identical components fail, control can be continued. In addition, as described in the first embodiment, by connecting the signal lines by the inter-system connection line, the output can be the same as that in the normal state unless the failure occurs on the drive side. In a case where an inter-system connection line is provided, it is preferable to appropriately insert an isolator in order to avoid a common cause failure.

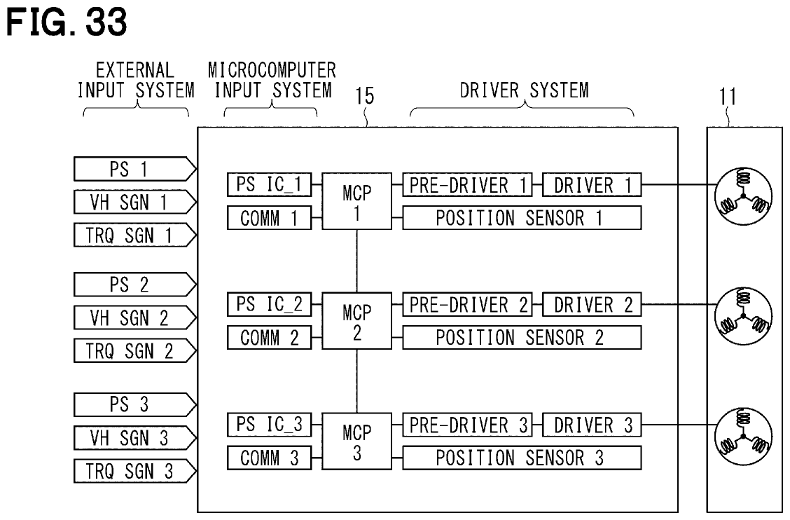

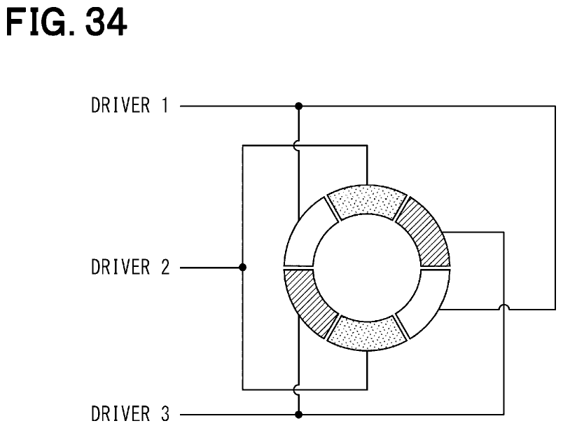

In addition, the present disclosure is not limited to an even system such as two systems or four systems, but may be an odd system, or may be a system in which a system having an odd number of components and a system having an even number of components are mixed. The sixth embodiment illustrated in FIG. 33 is an example of a three-system configuration in which three external input systems, three microcomputer input systems, three driver systems, and three motor windings are provided. As illustrated in FIG. 34, in a case where the number of driver systems is three, the number of motor windings is three, so that wiring can be efficiently performed.

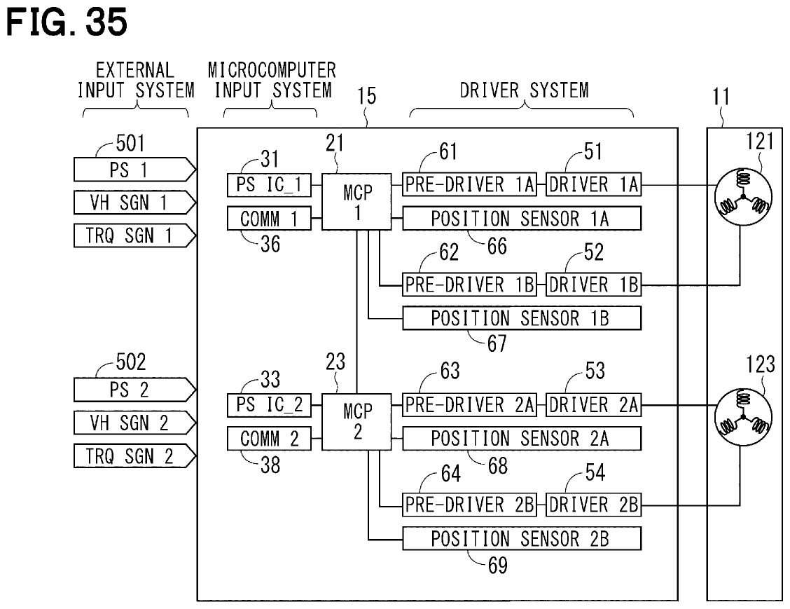

On the other hand, when redundancy is achieved by providing a plurality of components, there are concerns about an increase in the number of components, an increase in size, and an increase in computational load. In this case, three systems or four systems may be used for components that are relatively likely to fail, and two systems may be used for components that are relatively unlikely to fail. For example, in a case where the driver circuit is most likely to fail, as in the seventh embodiment illustrated in FIG. 35, the driver system is set to four systems, and the other systems are set to two systems.

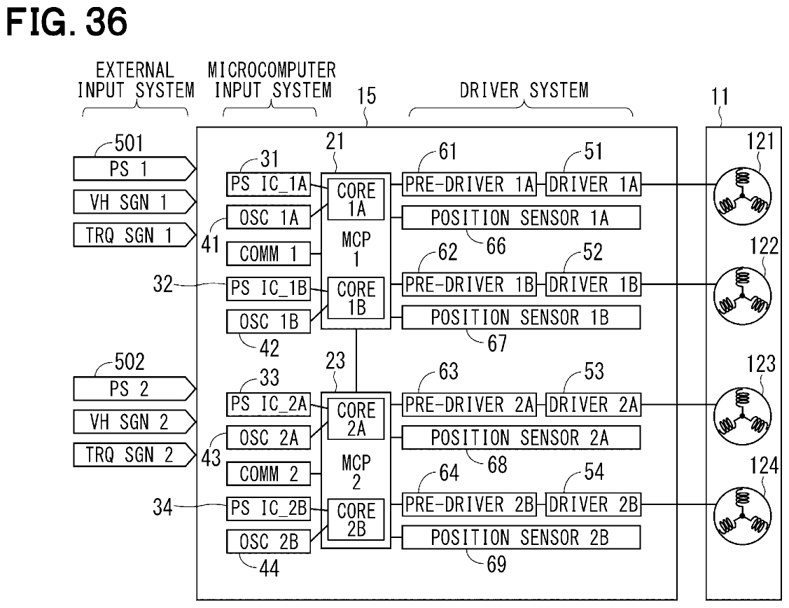

As in the eighth embodiment illustrated in FIG. 36, the ECU 15 may include four power supply ICs 31 to 34 and four oscillators 41 to 44, and a plurality of power supply ICs and a plurality of oscillators (two in FIG. 36) may be provided for one microcomputer. In the present embodiment, four processing cores are provided as a whole, and the processing cores include different power supply ICs as power supply sources, and include different oscillators as clock sources. Even with such a configuration, the same effects as those of the above embodiment are obtained.

### Ninth embodiment

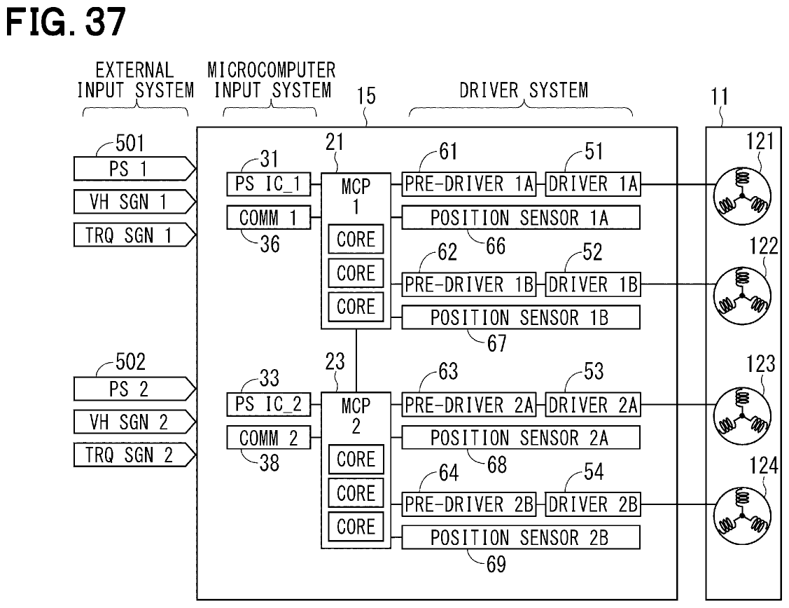

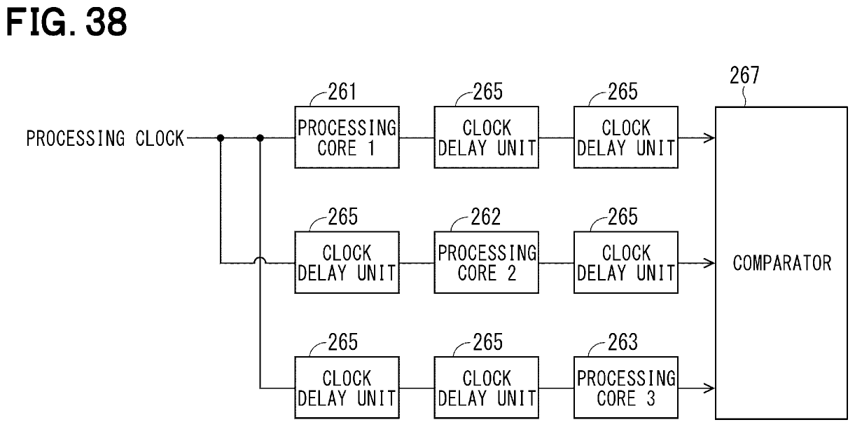

A ninth embodiment is illustrated in FIGS. 37 and 38. In the above embodiment, it is described that the processing core has the lockstep. In a case where the processing core has the lockstep, the redundant computation is performed by the lockstep core, and the abnormality detection is performed by comparing the computation results. On the other hand, in a case where the processing core does not have a lockstep core, a computation error cannot be detected. The ninth embodiment is an example in which the processing core does not have a lockstep core, and the microcomputers 21 and 23 each have three processing cores and perform abnormality monitoring by majority decision of the computation results.

As illustrated in FIG. 38, the three processing cores 261 to 263 can perform the computation independently, and can perform the computation simultaneously based on a common clock. In this case, for example, in a case where instantaneous noise is introduced, there is a possibility that the computations by the three processing cores 261 to 263 are similarly affected. Therefore, by shifting the timing of the computation using the clock delay unit 265, it is possible to prevent simultaneous occurrence of a computation error. Note that, in a comparator 267 that compares computation results, it is necessary to compare computation results at the same timing, and thus, delay amounts between the plurality of cores are organized. By dynamically comparing using the comparator 267, it is possible to perform determination at high speed. In addition, instead of the comparison by the comparator 267, data may be stored for a certain period of time, and the comparison may be collectively performed by the processing cores 261 to 263. Even with such a configuration, the same effects as those of the above embodiment are obtained.

### Tenth Embodiment

A tenth embodiment is illustrated in FIGS. 39 to 41. In the tenth embodiment, how to operate in a redundant configuration will be described. For example, in the case of a configuration in which four microcomputers and four motor windings are provided (see FIG. 32), the four microcomputers may be uniformly driven, and the output per set of motor windings may be set to 25%.

In addition, the two microcomputers and the two sets of motor windings are set to a drive system, the remaining two microcomputers and the remaining two sets of motor windings are set to a backup system, and the output per set of motor windings is set to 50% by performing driving in the drive system in the normal state. In addition, in a case where an abnormality occurs in the drive system, the driving is switched to the driving in the backup system.

FIG. 39 illustrates an example in which there are four microcomputers 21 to 24 and four driver circuits 51 to 54 and two sets of motor windings 121 and 123, the microcomputers 21 and 22 and the driver circuits 51 and 52 are connected to the motor winding 121, and the microcomputers 23 and 24 and the driver circuits 53 and 54 are connected to the motor winding 123. The motor relay 131 is provided between the driver circuit 51 and the motor winding 121, the motor relay 132 is provided between the driver circuit 52 and the motor winding 122, the motor relay 133 is provided between the driver circuit 53 and the motor winding 123, and the motor relay 134 is provided between the driver circuit 54 and the motor winding 124. The motor relays 131 to 134 include three switching elements corresponding to the respective phases. In the figure, the motor relay is referred to as an “SW”.

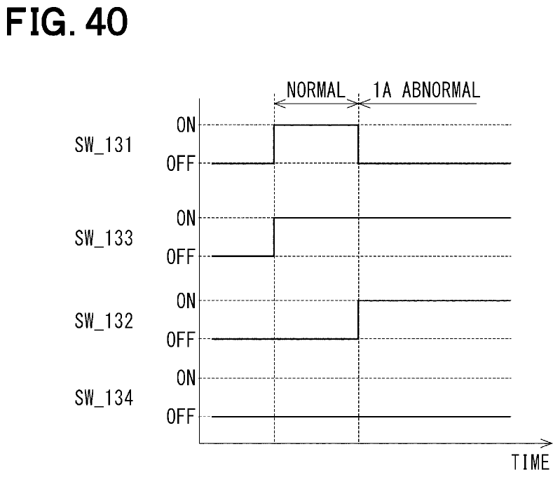

As illustrated in FIG. 40, in the normal state, the motor relays 131 and 133 are turned on to energize the motor windings 121 and 123 using the driver circuits 51 and 53, thereby driving the motor 11. In a case where an abnormality occurs in the microcomputer 21, the motor relay 131 is turned off, and the motor relay 132 is turned from off to on to energize the motor winding 121 using the driver circuit 52 instead of the driver circuit 51. When the microcomputer 23 is normal, the motor relay 133 is kept on and the motor relay 134 is kept off.

Similarly, in a case where an abnormality occurs in the microcomputer 23, the motor relay 133 is turned off, and the motor relay 134 is turned from off to on to energize the motor winding 123 using the driver circuit 54 instead of the driver circuit 53. When the microcomputer 21 is normal, the motor relay 131 is kept on and the motor relay 132 is kept off. As a result, even in a case where an abnormality occurs in the microcomputers 21 and 23, the motor 11 can be continuously driven in the same state as before the occurrence of the abnormality.

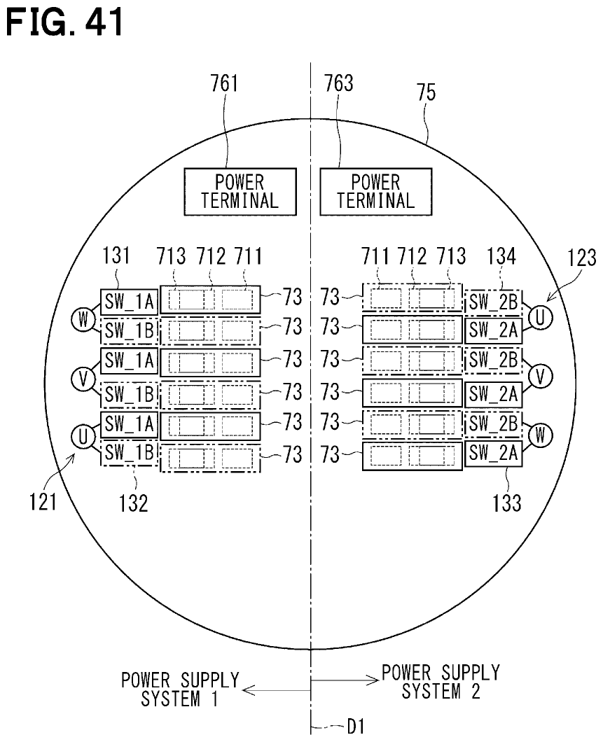

As illustrated in FIG. 41, the components related to the energization of the motor winding 121 are collectively disposed on one side (the left side of the sheet in the example of FIG. 41) of the substrate 75, and the components related to the energization of the motor winding 123 are collectively disposed on the other side (the right side of the sheet in the example of FIG. 41) of the substrate 75.

On the substrate 75, the power terminals are disposed line-symmetrically with respect to the substrate division line D1. The extraction wires of the motor windings 121 and 123, the driver component 73, and the motor relays 131 to 134 between the motor wires and the driver components are disposed line-symmetrically with respect to the substrate division line D1 in the configuration with respect to the motor winding 121 and the configuration with respect to the motor winding 123, and the phase arrangement is disposed in the reverse order.

In the driver component 73, one high-side chip 712 and one low-side chip 713 corresponding to each phase, and a control chip 711 incorporating a pre-driver IC corresponding thereto are integrally sealed. The six driver components 73 are disposed side by side with the element-side end portions facing the motor windings 121 and 123 and the IC-side end portions facing the substrate division line D1.

In the driver component 73, the low-side chip 713, the high-side chip 712, and the control chip 711 are disposed in this order from the motor windings 121 and 123. The low-side chip 713 is shifted from and stacked on the high-side chip 712, but may be in a flat state without being stacked, or the control chip 711 may be a separate body. The driver components 701 to 704 of the above embodiment in which a total of six switching elements are modularized may be used. In this case, the elements of the drive system and the elements of the backup system are allocated to different modules in the phase (the V phase in the example of FIG. 41) disposed in the middle.

In FIG. 41, the components of the drive system are indicated by solid lines, the components of the backup system are indicated by two-dot chain lines, and the driver components of the drive system and the driver components of the backup system corresponding to each phase are alternately disposed adjacent to each other. Therefore, the high-side chips 712 and the low-side chips 713 used for in-phase driving are disposed adjacent to each other. As a result, the driver component 73 and the motor windings 121 and 123 can be easily wired, and the mounting area of the power unit on the substrate can be suppressed.

In the present embodiment, the upper arm elements and the lower arm elements are bridge-connected to constitute the driver circuits 51 to 54, and the plurality of driver circuits 51 to 54 are provided for each of the motor windings 121 to 124. With this configuration, even when an abnormality occurs in a part of the driver circuits, the driving of the motor 11 can be continued using the other driver circuits.

The high-side chips and the low-side chips of the different driver circuits connected to the same phases of the motor windings 121 to 124 are arranged adjacent to each other. With this configuration, the substrate wirings for connecting the driver components 73 constituting the plurality of driver circuits and the motor windings 121 to 124 can be simplified.

The motor relays 131 to 134 that switch the driver circuits used for driving the motor 11 are provided between the motor wire connection portions and the driver components 73. With this configuration, the driver circuits used for the driving can be appropriately switched. Further, the same effects as those of the above embodiment are obtained.

### Eleventh Embodiment to Thirteenth Embodiment

An eleventh embodiment to a thirteenth embodiment are variations of power terminal arrangement and connection. As in the eleventh embodiment illustrated in FIG. 42, in a case where four external input systems are provided (see FIG. 32), the power terminals 761 to 764 corresponding to the four connectors are uniformly disposed at 90° intervals.

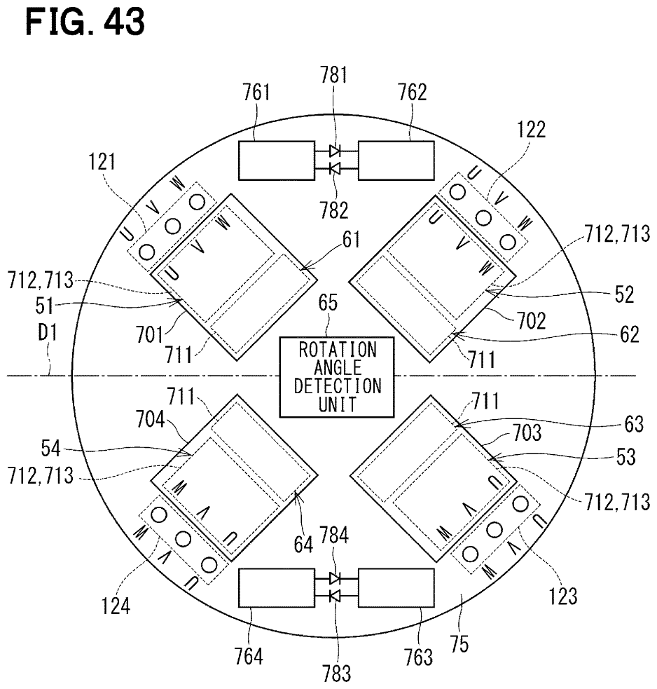

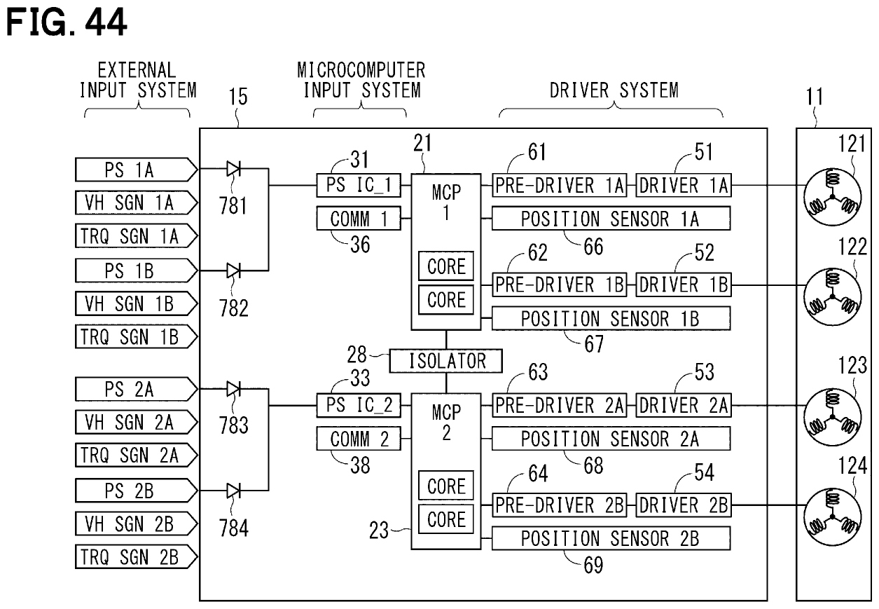

As in a twelfth embodiment illustrated in FIGS. 43 and 44, the power terminal 761 and the power terminal 762, and the power terminal 763 and the power terminal 764 may be disposed side by side at two positions on both sides of the substrate division line D1 on the outer edge of the substrate 75. In a case where four sets of power terminals 761 to 764 corresponding to four connectors are provided for the two power supply ICs 31 and 33, the two sets of power terminals 76 are connected to the respective power supply ICs 31 and 33 via the diodes 781 to 784. By electrically connecting the plurality of power supply inputs, power supply can be appropriately continued even in a case where connector abnormality, harness disconnection, or the like occurs.

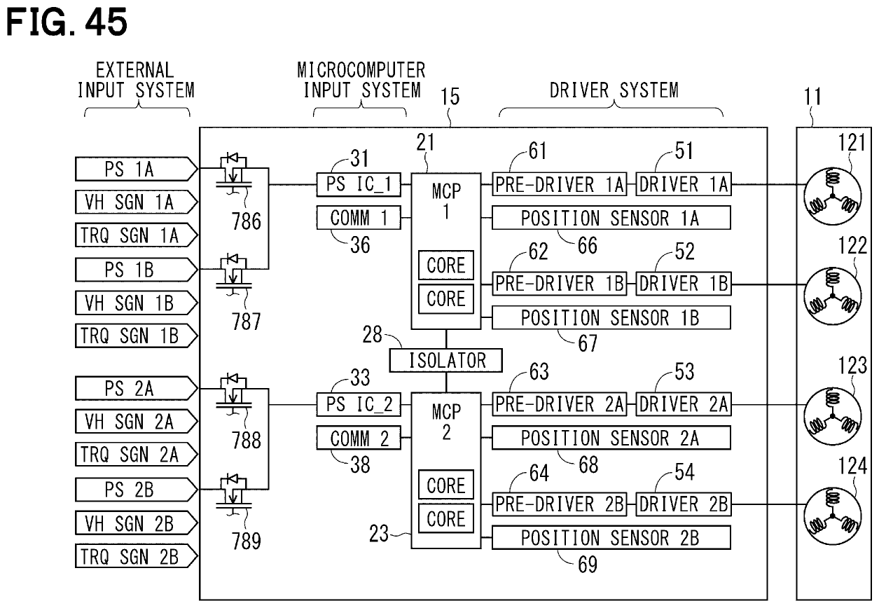

As in the thirteenth embodiment illustrated in FIGS. 45 to 47, the switching elements 786 to 789 may be provided between the connector and the power supply IC instead of the diodes 781 to 784. The switching elements 786 and 787 are connected to the power supply IC 31, and the switching elements 788 and 789 are connected to the power supply IC 33.

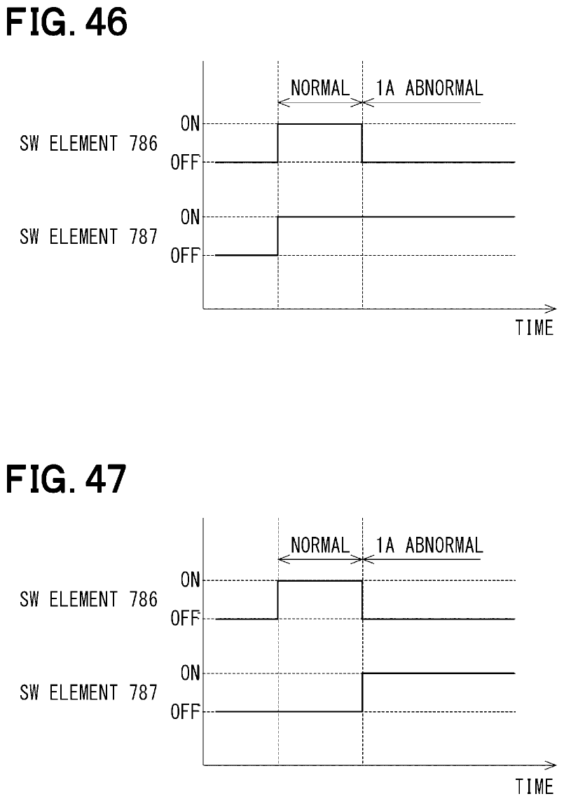

As illustrated in FIG. 46, both the switching elements 786 and 787 are turned on in the normal state, and in a case where an abnormality occurs in the power supply 1A, the switching element 786 where the abnormality occurs is turned off. In a case where an abnormality occurs in the power supply 1B, the switching element 787 is turned off. By turning on both switching elements 786 and 787 in the normal state, it is possible to quickly switch the power supply to be used when an abnormality occurs.

In addition, as illustrated in FIG. 47, in the normal state, the switching element 786 is turned on and the switching element 787 is turned off so that power is supplied from one power supply (for example, the power supply 1A). In a case where an abnormality of the power supply 1A is detected, the switching element 786 may be turned off, a wake-up signal may be transmitted from the normal microcomputer to the switching element 787, and the switching element 787 may be turned on. As a result, current consumption in the normal state can be suppressed. The same applies to the control of the switching elements 788 and 789 connected to the power supply IC 33.

In the tenth embodiment and the eleventh embodiment, the ECU 15 further includes the power supply ICs 31 and 33 connected to the plurality of power supplies 501 to 504. In the wirings that connect the power supplies 501 to 504 and the power supply ICs 31 and 33, power supply connection elements are provided for each power supply. In the tenth embodiment, the power supply connection elements are diodes 781 to 784, and in the eleventh embodiment, the power supply connection elements are switching elements 786 to 789 capable of being switched on and off. During normal operation, one switching element 786 is turned on and another switching element 787 is turned off, and when an abnormality occurs in power supply, the switching element to be turned on is switched. Thus, even when an abnormal power supply from a part of the power supplies occurs, driving of the motor 11 can be continued by switching the power supply. Further, the same effects as those of the above embodiment are obtained.

### Fourteenth Embodiment, Fifteenth Embodiment

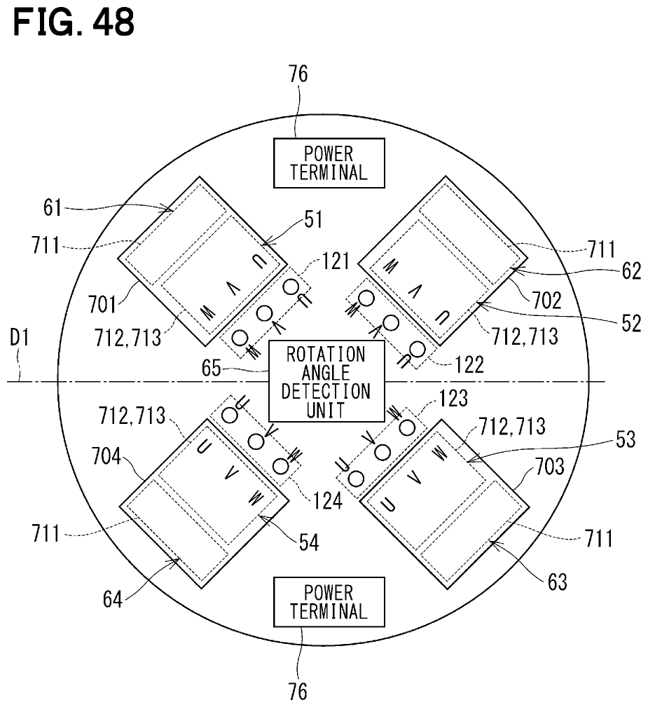

A fourteenth embodiment and a fifteenth embodiment are variations of the substrate arrangement. In the first embodiment, the motor windings 121 to 124 are provided at the radially outer side of the driver components 701 to 704 (see FIG. 11). In the fourteenth embodiment illustrated in FIG. 48, the motor windings 121 to 124 are provided at the radially inner side of the driver component 701.

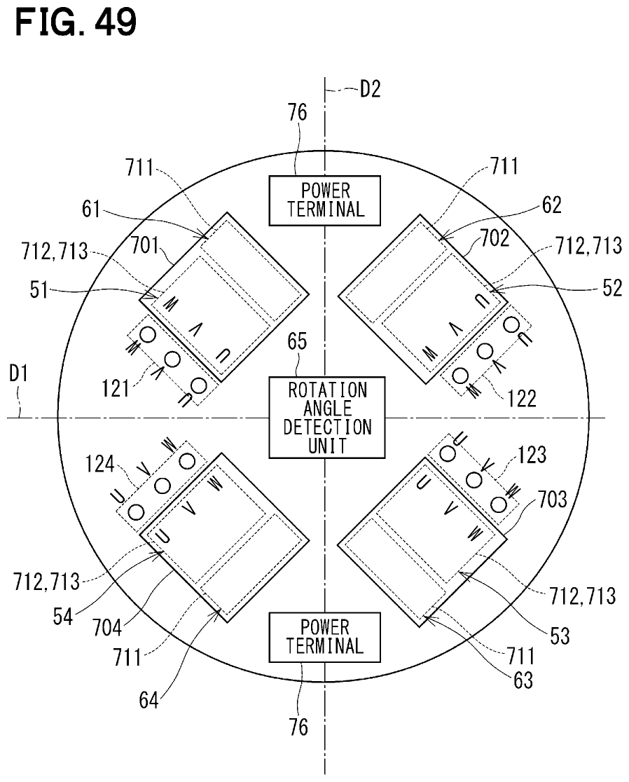

In addition, in the fifteenth embodiment illustrated in FIG. 49, the driver components 701 and 702 are disposed line-symmetrically with respect to the substrate center line D2 so that the pre-driver ICs 61 and 62 face the power terminal 76. In addition, the driver components 703 and 704 are disposed line-symmetrically with respect to the substrate center line D2 so that the pre-driver ICs 63 and 64 face the power terminal 76. The motor windings 121 to 124 are provided close to the driver circuits 51 to 54 of the driver components 701 to 704.

In the fourteenth embodiment, the control chip 711, the high-side chip 712 and the low-side chip 713, and the motor line connection portion are arrayed in this order from the radially outer side. In the fifteenth embodiment, four sets of the motor windings 121 to 124 and the driver components 701 to 704 are provided, and are respectively arranged in regions defined by the substrate division line D1 and the substrate center line D2 orthogonal to the substrate division line D1. In each region, the arrangement is such that the winding connection portion is adjacent to the substrate division line D1 and the control chip 711 is adjacent to the substrate center line D2. Even with this configuration, the same effects as those of the above embodiments are obtained.

### Sixteenth Embodiment

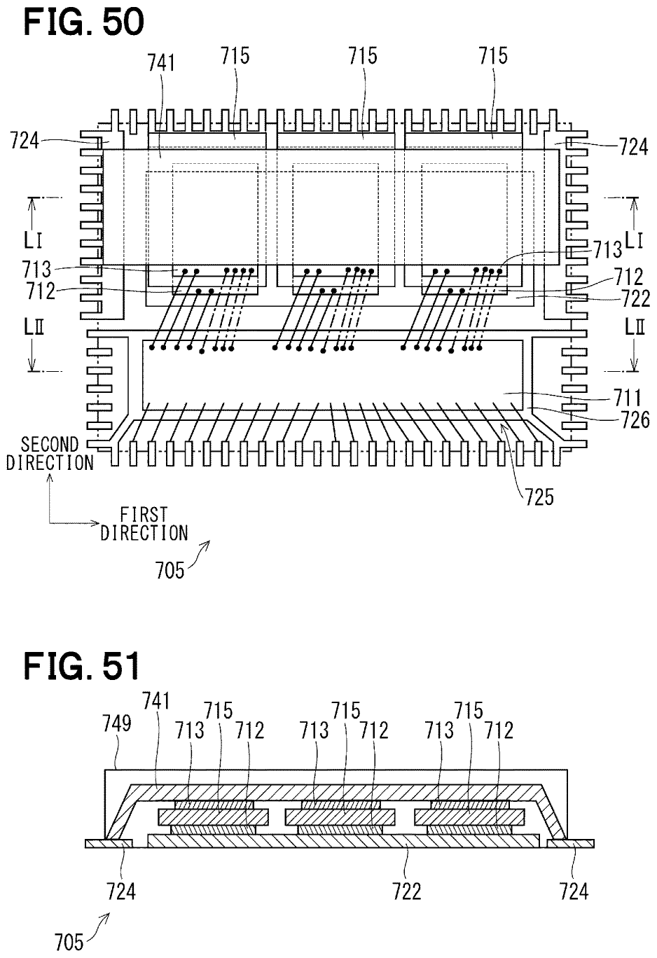

A sixteenth embodiment to an eighteenth embodiment are modifications of the driver component. The sixteenth embodiment is illustrated in FIGS. 50 to 52. FIG. 50 is a view corresponding to FIG. 7, and illustrates each component in a simplified manner. In a driver component 705 of the present embodiment, the stacked structure of the chips 712 and 713 is substantially the same as that of the first embodiment.

The ground lands 724 of a lead frame 725 are provided on both sides of the power land 722. The ground clip 741 is bent downward on both sides in the width direction and connected to the ground land 724.

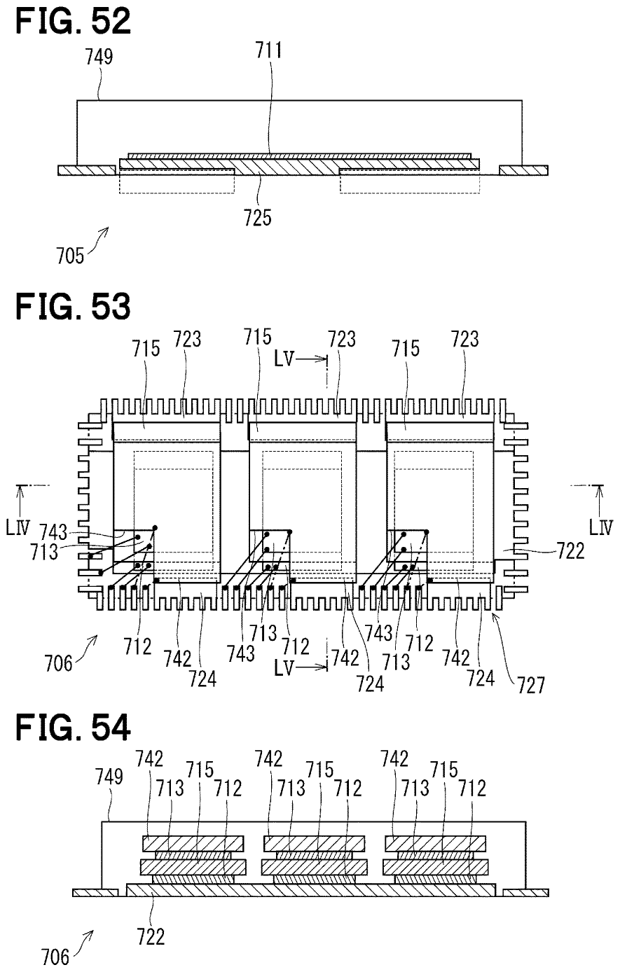

As illustrated in FIG. 52, a control land 726 where the control chip 711 is disposed is exposed to the back face from the sealing part 749 at the intermediate portion in the width direction, and is not exposed from the sealing part 749 on the outer side in the width direction. In other words, as indicated by a dashed square, part of the control land 726 is spaced apart from the substrate 75. As a result, it is possible to ensure substrate routing capability between the high-side chip 712 and the power supply line. In addition, since the power supply +line and the GND line are in a straight line, it is easy to arrange a miscellaneous protection element such as a snubber element (not illustrated). Furthermore, a noise loop can be reduced. Further, the same effects as those of the above embodiment are obtained.

### Seventeenth Embodiment

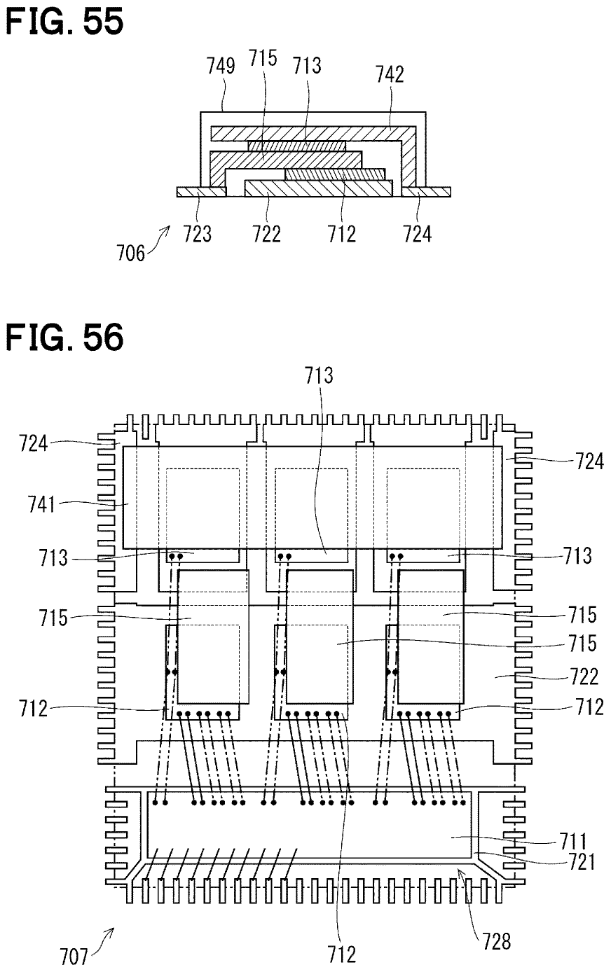

A seventeenth embodiment is illustrated in FIGS. 53 to 55. In a driver component 706 of the present embodiment, the control chip 711 is not built in, and a lead frame 727 does not include the control land 726. The stacked structure of the chips 712 and 713 is substantially the same as that of the first embodiment. Note that the control chip 711 may be built in the present embodiment. In the embodiment such as the first embodiment, the control chip 711 may be separately provided without being built in the driver component.

In the present embodiment, the ground land 724 is divided for each phase and is disposed opposite to the output land 723 with the power land 722 interposed therebetween. A ground clip 742 is provided for each phase. Each of the ground clips 742 is provided on the upper side of the low-side chip 713, and is bent downward to be connected to the ground land 724. The ground clip 742 has a notch portion 743 so that part of each of the high-side chip 712 and the low-side chip 713 is exposed to the top face. As a result, the non-overlapping region is ensured, and the high-side chip 712 and the low-side chip 713 can be connected to the signal line.

The motor current can be detected by dividing the ground clip 742 for each phase and detecting the voltage across the low-side chip 713 and the ground land 724. That is, in the present embodiment, the ground clip 742 also has a function as a current detection element. Thus, the motor current can be detected with a relatively simple configuration. Further, the same effects as those of the above embodiment are obtained.

### Eighteenth Embodiment

FIG. 56 illustrates an eighteenth embodiment. In a driver component 707 of the present embodiment, the high-side chip 712 and the low-side chip 713 are not stacked and are placed side by side in a planar manner. In the present embodiment, the control chip 711, the high-side chip 712, and the low-side chip 713 are disposed in this order from one side.

A lead frame 728 of the present embodiment includes a control land 721, a power land 722, an output land 729, and a ground land 724, and the low-side chip 713 is disposed on the output land 729. Each of the intermediate clips 715 is provided on the upper side of the high-side chip 712, and one end thereof is bent downward to be connected to the output land 729.

In the present embodiment, since the high-side chip 712 is disposed between the low-side chip 713 and the control chip 711, it is difficult to directly connect the gate electrode of the low-side chip 713 and the control chip 711. Therefore, in the present embodiment, a bonding pad is provided on the high-side chip 712, and the gate terminal of the low-side chip 713 and the control chip 711 are connected via the bonding pad of the high-side chip 712. By relaying the high-side chip 712 provided therebetween, the control chip 711 and the low-side chip 713 can be appropriately connected. Further, the same effects as those of the above embodiment are obtained.

In the embodiments, the ECU 15 corresponds to “motor control device”, the motor relays 131 to 134 correspond to “switching portions”, the diodes 781 to 784 and the switching elements 786 to 789 correspond to “power supply connection elements”, the substrate division line D1 corresponds to “first substrate center line”, and the substrate center line D2 corresponds to “second substrate center line”.

### Other Embodiments

In the above embodiments, the example in which the power supply system has 2 to 4 systems and the control system has 2 to 4 systems has been mainly described. In another embodiment, the number of power supply ICs, microcomputers, processing cores, pre-driver ICs, driver circuits, motor windings, and the like can be set in any number according to required redundancy, mounting space, and the like. In addition, the numbers of components may be different; for example, the number of fragile components (for example, a microcomputer or a driver circuit) may be four and the number of other components may be three.

In the above embodiments, the electronic component is mainly a driver component in which a pre-driver IC is built. In another embodiment, the electronic component is only required to be capable of performing digital communication with the microcomputer, and may be, for example, a pre-driver IC, a sensor, or the like provided separately from the driver circuit. In the above embodiments, it is described that the electronic components of the respective systems are the same. In another embodiment, the electronic components of the respective systems may have different outputs, different accuracy, and the like.

In the above embodiments, the communication device is applied to the electric power steering device. In another embodiment, the communication device may be applied to an in-vehicle device other than the electric power steering device, or may be applied to a device other than the in-vehicle device.

The control unit and the method thereof described in the present disclosure may be realized by a dedicated computer provided by configuring a processor and a memory programmed to execute one or a plurality of functions embodied by a computer program. Alternatively, the control unit and the method thereof described in the present disclosure may be realized by a dedicated computer provided by configuring a processor with one or more dedicated hardware logic circuits. Alternatively, the control unit and the method thereof described in the present disclosure may be realized by one or more dedicated computers configured by a combination of a processor and a memory programmed to execute one or a plurality of functions and a processor configured by one or more hardware logic circuits. Furthermore, the computer program may be stored in a computer-readable non-transitory tangible recording medium as an instruction executed by a computer. As described above, the present disclosure is not limited to the above embodiments at all, and can be implemented in various forms without departing from the gist of the present disclosure.

The present disclosure is described in accordance with the embodiments. However, the present disclosure is not limited to the embodiments and the structures. The present disclosure also includes various modifications and variations within the scope of equivalents. In addition, various combinations and modes, and other combinations and modes including only one element, more elements, or fewer elements therein are within the scope and idea of the present disclosure.

What is claimed is:

1. A motor control device that drives a motor having a plurality of motor windings, the motor control device comprising:
a plurality of driver components each including a high-side chip including an upper arm element connected to a high potential side, a low-side chip including a lower arm element connected to a low potential side of the upper arm element, and a control chip including a pre-driver integrated circuit (IC) configured to output drive signals to the upper arm element and the lower arm element; and
a substrate on which the driver components are mounted, wherein
the driver components are arranged on the substrate in regions divided for each of the driver components related to energization control of the respective motor windings, and
in each region, the control chip, the high-side and low-side chips, and a motor wire connection portion to which the motor winding is connected are arrayed in this order from one side.

2. The motor control device according to claim 1, wherein, on the substrate, the control chip, the high-side and low-side chips, and the motor wire connection portion are arrayed in this order from a radially inner side.

3. The motor control device according to claim 1, wherein, on the substrate, the control chip, the high-side and low-side chips, and the motor wire connection portion are arrayed in this order from a radially outer side.

4. The motor control device according to claim 1, wherein
the motor windings and the driver components are provided in four sets, and are respectively arranged in regions partitioned by a first substrate center line and a second substrate center line orthogonal to the first substrate center line, and
in each region, the driver component is arranged such that the motor wire connection portion is adjacent to the first substrate center line and the control chip is adjacent to the second substrate center line.

5. The motor control device according to claim 1, wherein
the low-side chip is stacked on a corresponding high-side chip in a state shifted so that a part of the high-side chip does not overlap.

6. The motor control device according to claim 1, wherein
the control chip is integrally sealed with the high-side chip and the low-side chip in a sealing part.

7. The motor control device according to claim 1, wherein
the substrate is supplied with electric power from a plurality of power sources, and
an isolator is provided at a location that connects components provided in regions having different power sources.

8. The motor control device according to claim 1, wherein
the upper arm elements and the lower arm elements are bridge-connected to constitute a plurality of driver circuits, and
the plurality of driver circuits are provided for one of the motor windings.

9. The motor control device according to claim 8, wherein
the high-side chips and the low-side chips of different driver circuits connected to a same phase of the motor winding are arranged adjacent to each other.

10. The motor control device according to claim 8, wherein
a switching portion that switches the driver circuit used for driving the motor is provided between the motor wire connection portion and the driver component.

11. The motor control device according to claim 1, further comprising:
a power supply IC connected to a plurality of power supplies, wherein
a power supply connection element is provided for each power supply in a wiring that connects the power supply and the power supply IC.

12. The motor control device according to claim 11, wherein
the power supply connection element is a diode.

13. The motor control device according to claim 11, wherein
the power supply connection element is a switching element capable of switching between on and off, and
during a normal operation, one of the power supply connection elements corresponding to one of the power sources is turned on and the other power supply connection elements are turned off, and
when an abnormality occurs in power supply, the power supply connection element to be turned on is switched.
